(19) United States
(12) Patent Application Publication
(10) Pub. No.: US 2011/0210347 A1
(43) Pub. Date: Sep. 1, 2011

(54) SEMICONDUCTOR DEVICE AND METHOD OF MANUFACTURING THE SAME

(75) Inventor: Toru TAKEGUCHI, Tokyo (JP)

(73) Assignee: MITSUBISHI ELECTRIC CORPORATION, Chiyoda-ku (JP)

(21) Appl. No.: 13/032,978

(22) Filed: Feb. 23, 2011

(30) Foreign Application Priority Data
Feb. 26, 2010 (JP) 2010-042515

(51) Int. Cl. H01L 33/08; H01L 21/84

(52) U.S. Cl. 257/88; 438/156; 257/E33.005; 257/E21.7

(57) ABSTRACT

A semiconductor device including: a thin film transistor substrate; and a driving circuit, wherein the thin film transistor substrate includes: a thin film transistor includes: a gate electrode; a gate insulating film that is formed on the insulating substrate and the gate electrode; a semiconductor layer that is formed on the gate insulating film; a channel protecting film; and a source electrode and a drain electrode that are formed to connect with the semiconductor layer; and a wiring converting unit that directly and electrically connects a first wiring layer and a second wiring layer through a first contact hole formed in the gate insulating film in the driving circuit, wherein the first wiring layer is formed at the same layer as the gate electrode on the insulating substrate; and wherein the second wiring layer is formed at the same layer as the source electrode and the drain electrode.

### CROSS-REFERENCE TO RELATED APPLICATION

This application claims priority from Japanese Patent Application No. 2010-042515 filed on Feb. 26, 2010, the entire subject matter of which is incorporated herein by reference.

### BACKGROUND

### Technical Field

The present invention relates to a semiconductor device having a thin film transistor in a display device and a photoelectric conversion device etc. and a method of manufacturing the same.

A liquid crystal display (hereinafter, also referred to as LCD), which is one of generally-used thin panel display devices, has been used widely in monitors of personal computers or portable information terminal devices, etc., due to merits of LCD, such as low power consumption, a small-sized and a lightweight. In recent years, the liquid crystal display also has been used as a TV panel instead of a CRT-based television. In addition, an electro-luminescence display device (hereinafter, referred to as EL), which resolves problems in the LCD, such as response speed for displaying the movie, a viewing angle, a contrast, also has been used as a thin panel display device. These display devices have a common feature, which uses semiconductor devices having a Thin Film Transistor (hereinafter referred to as TFT). Additionally, photoelectric conversion devices such as an image sensor, etc., also have a common feature, which uses semiconductor devices having thin film transistors. The TFT structure used in these semiconductor devices generally employs a Metal Insulator Semiconductor (hereinafter referred to as MIS) configuration using a semiconductor film. The TFT is classified by the structure into a bottom gate type (also called as a reverse stagger type) and a top gate type (also called as a coplanar type), etc. The semiconductor film is also classified into a non-crystalline semiconductor film or an amorphous semiconductor film, which have no crystalline configuration, and a polycrystalline semiconductor film, which has a crystalline configuration. Those TFT structures and the TFT semiconductor films are properly selected according to the intended usage and the intended performance of the display devices. Specifically, by using the crystalline semiconductor film, the TFT achieves superior transistor characteristics, such as high reliability and field effect mobility. Accordingly, if the TFT using a semiconductor film having the crystal structure is used, there are advantages that a driving circuit can be directly formed on a glass substrate (which is called a driving circuit embedded type), then cost-cutting by reducing the number of additional members, such as an external Integrated Circuit (IC), and making narrow flame, etc., can be achieved. Furthermore, in recent years, a microcrystalline semiconductor film has been employed in the TFT. The microcrystalline semiconductor film is a kind of semiconductor film having a crystal structure, a crystal diameter thereof is relatively fine. As a general method of manufacturing a polycrystalline semiconductor film, it is known a method that an amorphous semiconductor film is changed into a polycrystalline semiconductor film by irradiating an amorphous semiconductor film formed on the silicon oxide film, which is used as an under layer film, with a laser light (for instance, see JP-A-2003-017505). Meanwhile, it is known a method for forming a microcrystalline semiconductor film by using a plasma chemical vapor deposition (plasma CVD) method (for instance, see JP-A-8-094736).

Meanwhile, the method of manufacturing semiconductor devices, such as TFTs, requires a plurality of masking processes (a series of processes from forming a predetermined resist pattern on a film by photolithography to forming the film into a mask having predetermined pattern by using the patterned resist). However, the masking process, specifically the photolithography process, takes long time and high costs in the manufacturing method. Thus, in view of the cost, reducing the number of masking processes is required. Accordingly, it is preferable that a TFT structure can be manufactured by a small number of masking processes as far as possible. The reverse stagger type TFT structure is an example of an illustrative TFT structure capable of being manufactured in a relatively small number of masking processes. A back channel etching type TFT structure, which is a kind of the reverse stagger type configuration, needs a little mask process and is used in the TFT using an amorphous semiconductor film. In addition, in the manufacturing of the semiconductor device having TFTs, it is necessary to form a pixel electrode being connected to the TFT, a terminal electrode configuring a external terminal and a wiring converting unit, etc., with forming the TFT. (it may be a little changed according to the kind of semiconductor device.) Accordingly, to reduce the number of masking, it is important to reduce the total number of masking processes including processes forming the TFT structure and these related configurations. As described above, to reduce effectively the total number of masking processes for manufacturing the semiconductor device having the TFT, the TFT structure may employ a back channel etching type structure that is formed by the relatively small number of masking processes. And then, forming processes of the pixel electrode, the terminal electrode and the wiring converting unit, etc., may be shared with the masking process forming the TFT structure, as far as possible. For instance, in the related art using the back channel etching type TFT structure, the wiring of the converting unit is formed by using common masking processes forming the gate electrodes and source/drain electrodes. In addition, the contact holes are formed by using common masking processes forming the contact holes that connect the TFTs with pixel electrodes. In this way, the manufacturing method in the related art reduces the number of masking processes. (see, JP-A-2000-081638).

### SUMMARY OF THE PRESENT INVENTION

A number of TFT using the polycrystalline semiconductor film of the related art, such as JP-A-2003-017505 and JP-A-8-094736, are employing the coplanar type TFT structure in spite of the large number of masking processes. As a result, the number of masking processes is not reduced. In other word, some problems are not solved in the back channel etching type configuration using the polycrystalline semiconductor film. The first problem will be described. The back channel etching processing in the formation of the back channel etching type TFT structure is performed to etch, remove and separate ohmic contact layers (silicon layers including n type impurity, hereinafter referred as n+Si layer) formed on the semiconductor film. Since a etching selectivity of the n+Si layers and semiconductor films in the etching process is not high, a condition is set between first etching condition, in which the n+Si layer is etched and separated sufficiently, and second etching condition, in which the semiconductor film is partially etched but a part of the semiconductor film is not separated and remains. Furthermore, considering a variation in the film thickness of the n+Si layer in a substrate or etching rate, it is necessary to set the film thickness relatively thicker so that the semiconductor film is not be separated and remains. In such condition, in case that the amorphous semiconductor film is used, it is possible to thicken the thickness, but in case that the polycrystalline semiconductor film is used, it is quite difficult to thicken the thickness. The reason is that the polycrystalline semiconductor film is formed by the method irradiating the amorphous semiconductor film with a laser light or the method by depositing directly the polycrystalline film by the plasma CVD processing. However, the former method is difficult to convert the thick amorphous semiconductor film into the polycrystalline semiconductor film because of the restriction of penetrate depth of the general laser light. Meanwhile, the formation rate of the film in the latter method is quite slow and hard to acquire the thick polycrystalline semiconductor film in view of practically productivity. Thus, it is difficult to achieve the reverse stagger type TFT structure using the polycrystalline semiconductor film, since it is difficult to form the thick polycrystalline semiconductor film. To avoid the first problem, there is a method using a stacked layer film, in which polycrystalline semiconductor films are layered as lower layers and relatively thick amorphous semiconductor films are layered as upper layers. Thus, the process margin for etching of the back channel is secured, and at the same time, the reverse stagger type TFT structure using the polycrystalline semiconductor film is formed. However, even in the reverse stagger type TFT structure using the stacked layer film of the amorphous semiconductor film and the polycrystalline semiconductor film, there is a second problem. In the stacked layer film of the amorphous semiconductor film and the polycrystalline semiconductor film, the amorphous semiconductor film has a relatively high light-absorption coefficient, so that an electron-hole pair is easily produced. Further, the hole-mobility in the polycrystalline semiconductor film is high. Accordingly, when the light is projected from a backlight, etc., it is assumed that the holes generated in the amorphous semiconductor film may be injected into the polycrystalline film. As a result, in case that a negative bias is applied to a gate electrode in the reverse stagger type TFT, leakage current is increase, and the crosstalk is appeared. As a result, the display quality is deteriorated. According to the first and second problems as described above, it is difficult to achieve the back channel etching type configuration using the polycrystalline semiconductor film. As a result, a semiconductor device including the TFT by using the polycrystalline semiconductor film having a superior transistor performance cannot be manufactured in a small number of masking processes.

Further, in the method of manufacturing the related art (for example, JP-A-2000-081638), since both a contact hole connecting wirings of the wiring converting unit and a contact hole connecting the TFT and pixel electrode are formed in the common mask process, a configuration, in which the wirings are connected by a transparent conductive oxide film, such as ITO etc., formed as a pixel electrode, is employed. However, the wiring converting unit is used in a region around the panel, for example an external terminal driving circuit. As a result, the wiring converting unit is often arranged in a position exposed to air. Further, in a semiconductor device including the driving circuit used in not only the LCD, wirings in the driving circuit are arranged close to each other, so that the wiring converting unit and the other wiring, which are applied with the potential different from each other, are also arranged closed to each other. Additionally, in a case of the LCD, a counter electrode, which is applied a potential different from the wiring converting unit, is provided on the surface of a color filter substrate. The counter electrode has a substrate spacing distance from the counter substrate and is relatively close to the wiring converting unit. In the region that the wiring converting unit is close to the wirings or electrodes, which are applied potentials different from the wiring converting unit, if dew condensation is produced from air, electro-chemical reaction is occurred due to the potential difference and the wetness. In addition, in a case of the LCD, electro-chemical reaction may be occurred due to potential difference and wetness in a liquid crystal, in similar to the above case. Because of the electro-chemical reaction, the transparent conductive oxide film in the wiring converting unit may be reduction-corroded, thereby causing broken wires. Further, in a case of the LCD, in the region outside a region surrounded by the seal holding the liquid crystal by facing the substrates, specifically, in the region adjacent the seal, wetness is easily produced due to the dew condensation and the electro-chemical reaction be easily occurred. Further, in the region adjacent the seal, current path may be formed by impurities attached to a sidewall of the seal, regardless of the internal side surrounded by the seal or the external side near the seal. As a result, a minute current may flow through a surface of the sidewall of the seal and the electro-chemical reaction may be accelerated.

Accordingly, in manufacturing of the semiconductor device having the TFT achieving improved performance and reliability of transistor, it has not realized an effective method achieving a high productivity with the small number of masking processes.

The present invention has been made in consideration of the above problems. The object of the present invention is to provide a semiconductor device having a TFT achieving an improved performance and reliability and a method that reduces the number of masking processes for improving the productivity.

According to one illustrative aspect of the present invention, a semiconductor device including: a thin film transistor substrate including a thin film transistor; and a driving circuit embedded in the thin film transistor substrate, wherein the thin film transistor substrate includes: the thin film transistor includes: a gate electrode that is formed on an insulating substrate; a gate insulating film that is formed on the insulating substrate and the gate electrode; a semiconductor layer that is formed on the gate insulating film, wherein a crystalline semiconductor part formed at least part of the semiconductor layer includes a channel region; a channel protecting film that is formed on the channel region of the semiconductor layer to protect the channel region; and a source electrode and a drain electrode that are formed to connect with the semiconductor layer; and a wiring converting unit that directly and electrically connects a first wiring layer and a second wiring layer through a first contact hole formed in the gate insulating film in the driving circuit, wherein the first wiring layer is formed at the same layer as the gate electrode on the insulating substrate; and wherein the second wiring layer is formed at the same layer as the source electrode and the drain electrode.

Accordingly, a semiconductor device having a TFT in the present invention achieves a superior performance, such as improved field effect mobility and lowered leakage current, a reduction of the number of additional elements, such as an external IC, and a prevention of corrosion, etc., caused by an electro-chemical reaction in the driving circuit.

### BRIEF DESCRIPTION OF THE DRAWINGS

FIG. 1 is a plan view showing a liquid crystal display panel of a liquid crystal display device according to a first illustrative aspect of the present invention;

FIG. 2 is a cross sectional view showing a TFT array substrate that is used in the liquid crystal display device according to a first illustrative aspect of the present invention;

FIG. 3A to FIG. 3G are cross sectional views illustrating a method of manufacturing the TFT array substrate that is used in the liquid crystal display device according to a first illustrative aspect of the present invention;

FIG. 4 is a plan view showing a mother liquid crystal cell substrate in a manufacturing process of the liquid crystal display device according to a first illustrative aspect of the present invention;

FIG. 5A to FIG. 5C are cross sectional views showing a method of manufacturing a TFT array substrate that is used in the liquid crystal display device according to a second illustrative aspect of the present invention;

FIG. 6A to FIG. 6D are cross sectional views showing a method of manufacturing a TFT array substrate that is used in the liquid crystal display device according to a second illustrative aspect of the present invention;

FIG. 7A to FIG. 7D are cross sectional views showing a method of manufacturing a TFT array substrate that is used in the liquid crystal display device according to a third illustrative aspect of the present invention;

FIG. 8 is a cross sectional view showing a method of manufacturing a TFT array substrate that is used in the liquid crystal display device according to an illustrative modification of the third illustrative aspect of the present invention;

FIG. 9A to FIG. 9D are plan views showing a method of manufacturing a TFT array substrate that is used in the liquid crystal display device according to an illustrative modification the third illustrative aspect of the present invention;

FIG. 10A and FIG. 10B are cross sectional views showing a method of manufacturing a TFT array substrate that is used in the liquid crystal display device according to a fourth illustrative aspect of the present invention; and

FIG. 11A to FIG. 11C are cross sectional views showing a method of manufacturing a TFT array substrate that is used in the liquid crystal display device according to a fourth illustrative aspect of the present invention.

### DESCRIPTION OF PREFERRED ILLUSTRATIVE ASPECTS

Hereinafter, illustrative aspects of the present invention will be described with reference to the drawings.

### (First Illustrative Aspect)

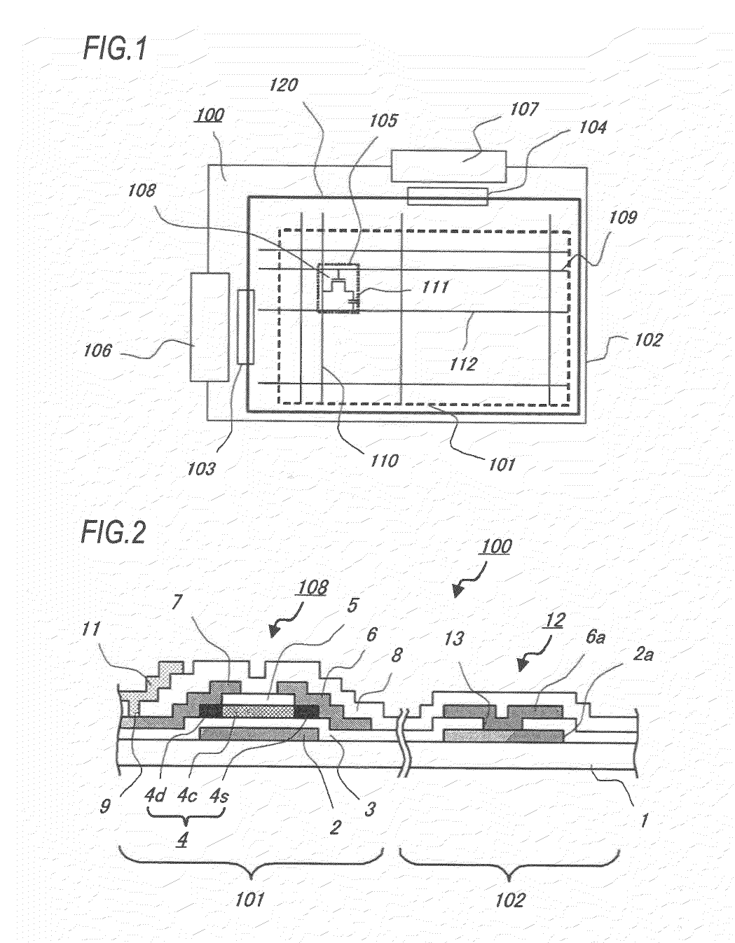

First, as an example of a semiconductor device having a TFT, a liquid crystal display device according to the first illustrative aspect of the present invention will be described. FIG. 1 is a schematic plan view showing the configuration of a liquid crystal display panel of a liquid crystal display device, which is a semiconductor device that functions as a display device, according to the first illustrative aspect of the present invention. The drawings show schematically the elements in the configuration, it does not indicate practically accurate size, etc., of the elements of the configuration. In addition, to avoid the complexity in the drawings, other elements than main elements may be omitted or a part of the configuration may be simplified, in the drawings. Hereinafter, the other drawings are also handled as mentioned above. Furthermore, in the following drawings, same elements are referred as same numerals in the drawings, and will not be described repeatedly.

The liquid crystal display panel, according to the first illustrative aspect of the present invention, is formed by two transparent insulating substrates having a light transmittal property, such as a glass substrate or a quartz substrate etc., and facing to each another. As shown in FIG. 1, a pixel TFT 108, which is a switching device for controlling a voltage applied to a liquid crystal between “ON” and “OFF” state, which is corresponding with a pixel that is a unit of displaying an image, and which is arranged on one of the transparent insulating substrate Since the pixel TFT 108 is provided on the substrate, the substrate is called as a thin film transistor substrate (TFT substrate). Meanwhile, since the pixel TFT 108 on the substrate is corresponding to every pixel in array state, the substrate is called as TFT array substrate 100. In addition, the TFT array substrate 100 includes a display region 101 that displays an image and a frame region 102 surrounding the display region 101. A plurality of gate wirings (scanning signal line) 109, a plurality of storage capacitance wirings 112 and a plurality of source wirings (display signal line) 110 is formed in the display region 101.

The plurality of gate wirings 109 and the plurality of storage capacitance wirings 112 are arranged in parallel and facing each other. The plurality of source wirings 110 are arranged in parallel with each other. Both the gate wiring 109 and the storage capacitance wiring 112 is arranged to be perpendicular to the source wiring 110. The pixel 105 is corresponding to each region surrounded by the gate wiring 109, storage capacitance wiring 112 and the adjacent source wiring 110. The pixel 105 is arranged in a matrix on the TFT array substrate 100.

At least one of pixel TFTs 108 and the storage capacitor 111 connected to the pixel TFT 108 are connected in series in the TFT 105. The pixel TFT 108 is a switching device for supplying a display voltage to a pixel electrode (not shown). The gate electrode of the pixel TFT 108 is connected to the gate wiring 109 for controlling “ON” and “OFF” state of the pixel TFT 108 in response to a gate signal that is supplied from the gate wiring 109. The source electrode of the pixel TFT 108 is connected to the source wiring 110. When the pixel TFT 108 is turned on, electric current flows from the source electrode to the drain electrode of the pixel TFT 108. Accordingly, a display voltage is applied to the pixel electrode connected to the drain electrode. Consequently, an electric field corresponding to a display voltage is applied between the pixel electrode and the counter electrode (will be described in detail later). Additionally, the storage capacitor 111 is connected to the pixel electrode in parallel. Accordingly, the voltage is applied to the pixel electrode, and, at the same time, the voltage is applied to the storage capacitor 111. In addition, the capacitance of the storage capacitor 111 is set larger than the capacitance between the pixel electrode and the counter electrode. Thus, electrical charge is maintained for a relatively long time.

Furthermore, a scanning signal driving circuit 103 and a scanning signal driving circuit 104 is provided in the frame region 102 of the TFT array substrate 100. That is, the TFT array substrate 100 includes a driving circuit configured by the scanning signal driving circuit 103 and the scanning signal driving circuit 104. In addition, the scanning signal driving circuit 103 and the scanning signal driving circuit 104 are configured by a driving TFT (not shown) that is formed at the same time as the formation of the pixel TFT 108 in the display region 101. The gate wiring 109 is extended from the display region 101 to the frame region 102. The gate wiring 109 is connected to the scanning signal driving circuit 103. The source wiring 110 is also extended from the display region 101 and connected to the scanning signal driving circuit 104.

Hereinafter, the other configuration relating to the liquid crystal display device will be described. Each the external wiring 106 and the external wiring 107 connects each the scanning signal driving circuit 103 and the scanning signal driving circuit 104 to each external terminals provided on the two sides end of the TFT array substrate 100. The external wiring is a wiring substrate such as Flexible Printed Circuit (FPC) etc. Various signals from an external device is supplied to both the scanning signal driving circuit 103 and the scanning signal driving circuit 104 through both the external wiring 106 and the external wiring 107. In response to the various signals, a gate signal (scanning signal) is supplied to the gate wiring 109 by the scanning signal driving circuit 103, a display signal is supplied to the source wiring 110 by the scanning signal driving circuit 104. Thus, the TFT 108 is sequentially selected, and a display voltage corresponding to a display data is supplied to each pixel 105. In addition, an alignment film is formed on the uppermost surface of the TFT array substrate 100. The TFT array substrate 100 is formed as described above.

Furthermore, a counter substrate (not shown) is provided to face with the TFT array substrate 100. The counter substrate is, for instance, a color filter substrate and arranged in a displayed side. A color resists (colored material), black matrix (BM), counter electrode and alignment film etc. may be formed on a surface of the counter substrate. Incidentally, in a case of a liquid crystal display device using In-Plane Switching (IPS) method, the counter electrode is arranged in the TFT array substrate 100. And, the TFT array substrate 100 and the counter substrate are bonded the seal 120, which is provided in the frame region 102 and is surrounding the display region 101. In addition, liquid crystal (not shown) is sealed in the region that is surrounded by the TFT array substrate 100, the counter substrate and the seal 120. According to the liquid crystal display device of the first illustrative aspect of the present invention, the TFT array substrate 100 and the counter substrate are arranged so that the pixel electrode and the counter electrode face each other, that is, the pixel electrode and the counter electrode is provided at a liquid crystal side. Further, optical sheets, such as polarizing plate and phase difference plate, are provided at external side of the TFT array substrate 100 and the counter substrate. And, a backlight unit, etc., is provided in counter view side in the above described liquid crystal display device. The liquid crystal display device of the first illustrative aspect is formed as described in the foregoing.

Next, the display operation of the liquid crystal display device will be briefly described, according to the first illustrative aspect of the present invention. The liquid crystal is drove by electric field between the pixel electrode and the counter electrode. Consequently, the alignment direction of liquid crystal between the substrates is changed, and the amount of light transmitted through a liquid crystal is also changed. That is, the amount of light transmitted toward the view side through a polarizing plate among the entire amount of light transmitted from the backlight unit is changed. The alignment direction of liquid crystal is changed in response to a display voltage applied. Accordingly, the amount of light transmitted toward the view side through the polarizing plate can be changed by controlling to the applied display voltage. That is, the amount of light viewed as image is controlled. The storage capacitor 111 serves to maintain the display voltage in a series of operations.

Next, configurations of the pixel TFT 108 arranged in the display region 101 of the TFT array substrate 100 and the wiring converting unit 12 arranged in the frame region 102 will be described in detail with reference to FIG. 2. FIG. 2 is a schematic cross sectional view showing the pixel TFT 108 formed in the display region 101 and the wiring converting unit 12 formed in the frame region 102, in which the scanning signal driving circuit 103, the scanning signal driving circuit 104, and an external terminal, etc., are provided in the TFT array substrate 100. For example, the gate electrode 2 is formed on the transparent insulating substrate 1 that is made of glass substrate having a light transparency. Next, the gate insulating film 3 is formed by a stacked film that includes a lower layer made of a silicon nitride film (SiN film) and an upper layer made of a silicon oxide film (SiO film). The gate insulating film 3 is covered the stacked film. The semiconductor layer 4 made of a crystalline silicon film is formed on the gate insulating film 3. The semiconductor layer 4 includes a source region 4s, channel region 4c and drain region 4d in a TFT. The source region 4s and the drain region 4d are doped with impurity, the resistance thereof is lower than the channel region 4c. In addition, the channel region 4c is made of a film of crystal grain, which is approximately equal to or less than about the size of 100 nm. That is a microcrystalline silicon film. Further, a channel protecting film 5 made of an inorganic insulating film the channel region 4c, which is formed by stacked film including a lower layer made of a silicon oxide film (SiO film) and an upper layer made of a silicon nitride film (SiN film), and that covers the channel region 4c to protect it. Furthermore, the source electrode 6 and drain electrode 7 are formed to cover the portion of the channel protecting film 5 and to connect the source region 4s and drain region 4d of the semiconductor layer 4. In other words, each the source region 4s and the drain region 4d of the semiconductor layer 4 doped with impurities are formed at a connecting portion that connects each the source electrode 6 and the drain electrode 7. According to the first illustrative aspect of the present invention, since the source region 4s and drain region 4d, which are doped with impurities by means of ion doping method, are formed on a entire region not covered with the channel protecting film 5 in the semiconductor layer 4, the turn-on characteristics of the TFT is improved. Furthermore, the protective insulating film 8 is formed to cover both the source electrode 6 and the drain electrode 7. Accordingly, the pixel TFT 108 is configured by a configuration of a channel protecting film type TFT in which microcrystalline silicon is used in a channel region. Further, a contact hole 9 is formed in the protective insulating film 8, the pixel electrode 11 formed on a protective insulating layer 8 is connected to the drain electrode 7 of the pixel TFT 108 through the contact hole 9. The driving TFT is formed in the scanning signal driving circuit 103 and scanning signal driving circuit 104 and has the similar configuration as the channel protecting film type TFT used in the pixel TFT 108, as mentioned above. However, in the driving TFT, the pixel electrode 11 and the contact hole 9 for connecting the pixel electrode 11 to the drain electrode 7 may be omitted. Also, the gate wiring 109 and storage capacitance wiring 112, which are not shown in FIG. 2, are formed at the same layer as the gate electrode 2, and the source wiring 110 is formed at the same layer as both the source electrode 6 and the drain electrode 7.

In the frame region 102 that the scanning signal driving circuit 103, the scanning signal driving circuit 104, an external terminal etc. is provided in the TFT array substrate 100, the wiring converting unit 12 is formed to connect electrically a wiring layer 2a, which is a first wiring layer formed in the same layer with the gate electrode 2, and a wiring layer 6a, which is a second wiring layer 6a formed in the same layer with both the source electrode 6 and the drain electrode 7. The wiring layer 2a may be a part of the gate wiring 109, and the wiring layer 6a may be a part of the source wiring 110. In the wiring converting unit 12, a contact hole 13 is formed in the gate insulating film 3 which is provided between the layer, which includes the gate electrode 2 and the wiring layer 2a, and the layer, which includes with the source electrode 6, the drain electrode 7 and the wiring layer 6a. As a result, the wiring layer 2a is directly connected to the wiring layer 6a through the contact hole 13. Further, the protective insulating film 8, which covers the source electrode 6 and drain electrode 7 in the pixel TFT 108, is formed on the wiring converting unit 12 that includes the wiring layer 2a, the wiring layer 6a and the contact hole 13, thereby covering commonly the wiring converting unit 12 and the pixel TFT 108.

According to the liquid crystal display device of the first illustrative aspect of the present invention, the wiring converting unit that electrically connects the layer 2a, which is formed in the same layer with the gate electrode 2, and the wiring layer 6a, which is formed in the same layer both the source electrode 6 and the drain electrode 7, is formed as the wiring converting unit 12 in which the wiring layer 2a and the wiring layer 6a are electrically connected each other through the contact hole 13 provided in the gate insulating film 3, in case that it is positioned at the outer side of the region surrounded by the seal 120 in the frame region 102, specifically. In addition, the wiring converting unit, which electrically connects the wiring layer 2a and the wiring layer 6a in the scanning signal driving circuit 103 and the scanning signal driving circuit 104, is formed in such a manner that the wiring layer 2a and the wiring layer 6a are directly connected through the contact hole 13 provided in the gate insulating film 3, regardless of the inner side and external side of the region surrounded by the seal 120.

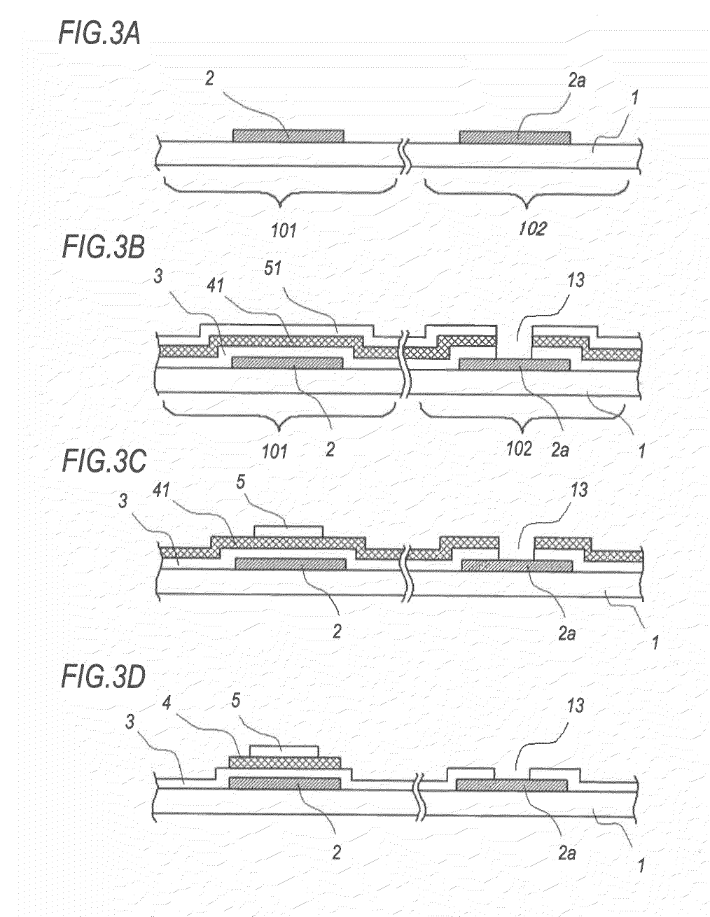

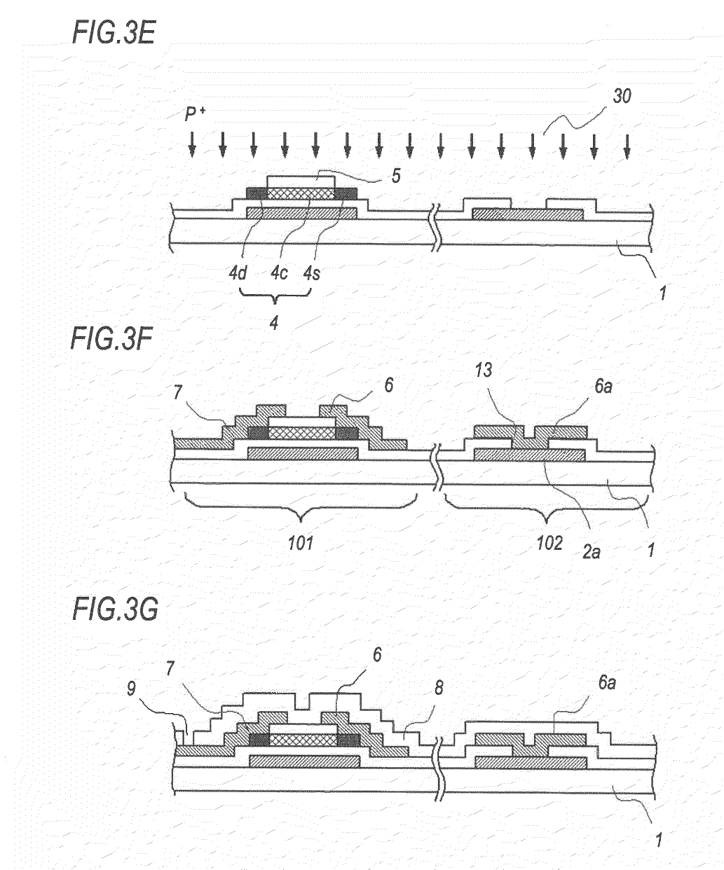

Next, the method of manufacturing the liquid crystal display device according to the first illustrative aspect of the present invention will be described. First, it will be described that the method of manufacturing the pixel TFT 108 arranged in the display region 101 and the wiring converting unit 12 arranged in the frame region 102, in the TFT array substrate 100, with reference to FIGS. 3A to 3G. FIGS. 3A to 3G are cross sectional schematic view showing the method of manufacturing the pixel TFT 108 and the wiring converting unit 12 on the TFT array substrate 100 according to the first illustrative aspect of the present invention.

First, a metal film is formed on the transparent insulating substrate 1 having a light transparency characteristic, such as a glass substrate or quartz substrate, etc., by means of DC magnetron sputtering method. According to the first illustrative aspect of the present invention, the transparent insulating substrate I is made of a non-alkaline glass substrate. The metal film is made of aluminum based material, specifically an aluminum based alloy metal including a predetermined amount of nickel and neodymium, is deposited in the thickness of about 200 nm. The metal film is patterned in a predetermined shape by using a related photolithography and a wet etching method, thereby forming the gate electrode 2 in the display region 101 at the same time as forming the wiring layer 2a in the frame region 102. That is, the gate electrode 2 and the wiring layer 2a are formed in the common masking processes. As a result, the gate electrode 2 and the wiring layer 2a are formed at the same layer. In addition, although it is not shown in drawing, the gate wiring 109 and the storage capacitance wiring 112 as shown in FIG. 1 are formed by a common masking process and formed at the same layer as the gate electrode 2 and wiring layer 2a. And, the wet etching is performed with a phosphoric acid based etching-solution. It is preferable that the end surface of the gate electrode 2 be formed in a taper shape. The taper shaped end surface improves a coatability of insulating film in a later depositing process, thereby improving the resistance property in the insulating film. According to the above processing, the configuration shown in FIG. 3A is acquired.

Next, a gate insulating layer 3, a crystalline semiconductor film 41 having a crystalline characteristic and a inorganic insulating film 51 is sequentially formed the transparent insulating substrate 1 including the gate electrode 2 of the display region 101 and the wiring layer 2a of the frame region 102. According to the first illustrative aspect of the present invention, after the gate insulating film 3 and the amorphous semiconductor film is sequentially formed, the amorphous semiconductor film is crystallized by irradiating with a laser light, thereby forming the crystalline semiconductor film 41. Then, the inorganic insulating film 51 is formed on crystalline semiconductor film 41. In more detail, the gate insulating film 3 is configured by a stacked film formed by a silicon nitride film (SiN film) and a silicon oxide film (SiO film). The silicon nitride film (SiN film) is deposited about 300 nm in thickness as an insulating film, and the silicon oxide film (SiO film) is deposited about 100 nm in thickness. However, the configuration of the gate insulating film 3 is not limited to the above configuration, and the thickness of the film is determined by considering the dielectric strength and the capacitance in the insulating film, etc. The amorphous semiconductor film to be transited into the crystalline semiconductor film 41 is formed by an amorphous silicon film in the thickness of about 50 nm. The SiN film and the SiO film forming the gate insulating film 3 and the amorphous silicon film forming the amorphous semiconductor film is sequentially formed by a deposition processes using a plasma CVD method. Since the amorphous silicon film formed by using the plasma CVD method contains a great amount of hydrogen therein, it is preferable that the amorphous silicon film be annealed at a high temperature to reduce the amount of hydrogen. In this aspect of the present invention, the chamber being maintained in low vacuum of nitrogen atmosphere is heated to 400 degrees Celsius, and then the substrate deposited with the amorphous semiconductor film is maintained at that status for 30 minutes. By performing above processing, it is possible to prevent the roughness on the surface of the semiconductor film due to an abrupt breakaway of hydrogen from the surface with increase in the temperature when the amorphous semiconductor film is crystallized. The amorphous silicon film, which is formed by above processing, is irradiated with a pulse laser light, thereby crystallizing. When irradiating thereon with a laser light, it is preferable that the amorphous semiconductor film is sprayed with non-volatile gas such as nitrogen for reducing the concentration of oxygen at the surface of the amorphous semiconductor. At this time, the laser light is shaped into a linear beam shape through a predetermined optical system, thereafter irradiating the amorphous semiconductor film. At this time, the amorphous semiconductor film is scanned first time. As a result, the amorphous semiconductor is melted and transitioned into the crystalline semiconductor film 41. In this illustrative aspect of the present invention, excimer laser (oscillation wavelength: 308 nm) is used as a laser light. Also, the linear beam shape of the laser light is about 200 μm by 200 mm, the scanning energy is 200 mJ/cm², and the scanning pitch is 15 μm. Herein, since the entire semiconductor film is crystallized, the present invention acquires a superior TFT, in which the drain current becomes high and the reliability is improved.

Thereafter, the silicon oxide film (SiO film) is formed in the thickness of about 30 nm, and further the silicon nitride film (SiN film) is formed in the thickness of 100 nm. The stacked film includes the SiO film and the SiN film is formed as the inorganic insulating film 50 that is to be the channel protecting film 5. According to the first illustrative aspect of the present invention as described above, the amorphous semiconductor film is formed and irradiated with a laser light for crystallizing. Thus, the crystalline semiconductor film 41 is formed. However, the crystalline semiconductor film 41 may be formed directly by means of a plasma CVD method. In this case, the gate insulating film 3, crystalline semiconductor film 41 and inorganic insulating film 51 that is to be the channel protecting film 5 may be continuously formed. With the continuously formation of the films, the simplification of the processes is achieved. Further, since the surface of the crystalline semiconductor film 41 is formed without exposing to air, it can prevent that the crystalline semiconductor film 41 is contaminated. As described above, the gate insulating film 3, the crystalline semiconductor film 41 having a crystalline characteristic and the inorganic insulating film 51 that is to be the channel protecting film 5 are formed. Thereafter, the gate insulating film 3, the crystalline semiconductor film 41 and the inorganic insulating film 51 that is to be the channel protecting film 5, which are respectively formed on the wiring layer 2a, are removed by using a related photolithography method and a dry etching method to connect the wiring layer 2a of the frame region 102. As a result, the contact hole 13 formed in the gate insulating film 3 is formed in a predetermined portion on the wiring layer 2a. Accordingly, the configuration shown in FIG. 3B is acquired.

Next, the inorganic insulating layer 51 is patterned in a predetermined shape by the related photolithography method and the dry etching method to form the channel protecting film 5. During the patterning and the removing of the inorganic insulating film 51 by the dry etching method, the same position as the removed portion of the inorganic insulating film 51 in the crystalline semiconductor film 41 is exposed by means of the dry etching processing. The inorganic insulating film 51 according to the illustrative aspect is formed by a stacked configuration of the lower SiO film and the upper SiN film. However, the inorganic insulating film 51 may be formed by a single layer of SiO film. During the process of dry etching for removing the inorganic insulating layer 51, in a case where the inorganic insulating film 51 is formed of a SiO film, it is necessary to secure enough time for etching (i.e., an over-etching time considering a margin) to remove sufficiently the inorganic insulating film 51, with considering that the etching rate for the SiO film is slow and the thickness of SiO film may be uneven. That is, the crystalline semiconductor film 41 is exposed for a long time in the dry-etching of the SiO film. Also, because of the low selectivity in etching between the SiO film and the crystalline semiconductor film 41 made of a microcrystalline film, it is difficult to remains the crystalline semiconductor film 41 due to the over etching. Accordingly, in case that the inorganic insulating film 51 is formed by the single SiO film, it is necessary to uniform the distribution of the thickness of SiO film or to thin the inorganic insulating film 51. However, the effect, which is covering and protecting the channel region 4c by the channel protecting film 5, is reduced or restricting the manufacturing process. Meanwhile, according to the first illustrative aspect, since the inorganic insulating film 51 has a stack configuration in which the SiN film having the effective selectivity in etching is deposited on a SiO film, the SiN film is etched first and then the SiO film is etched, so that the thickness of SiO film may be set as a thin film without a change in the thickness of the inorganic insulating layer 51. Accordingly, it is easy to remain the crystalline semiconductor film 41. In addition, it may improve the effect, which is covering and protecting the channel region 4c by the channel protecting film 5. Accordingly, the configuration shown in FIG. 3 C is acquired. Next, the crystalline semiconductor film 41 is formed in a predetermined pattern by means of a related photolithography method and a dry etching method, thereby forming the semiconductor layer 4. During the etching processing, the pattern edge of the semiconductor layer 4 is formed into a taper shape by the etching using the mixed gas of CF4 and O2 while setting back a photoresist. The taper shaped pattern improve the coatability of a metal film for forming wiring in later process and serves to prevent the wiring from breaking down, which is often occurred at the step of the pattern edge of the semiconductor layer 4. Accordingly, the configuration as shown in FIG. 3D may be acquired.

Next, by performing an ion implantation processing 30 in which phosphorus ion is doped by an ion doping method, an ohmic contact layer of n+Si layer is formed on a part of the semiconductor layer 4 other than the region covered with the channel protecting film 5. Here, the ion doping condition is set as the acceleration voltage 5 kV, and the dose amount is 1E15/cm2. The semiconductor layer 4 doped with phosphorus ions includes the source region 4s and the drain region 4d which are made of n+Si layer, and the other portion of the semiconductor layer 4 under the channel protecting film 5 includes the channel region 4c. Accordingly, the configuration shown in FIG. 3E is acquired. The order of the forming process of the crystalline semiconductor film 41 as described with reference to FIG. 3D and the doping process as described with reference to FIG. 3E may be exchanged. That is, the ion doping process, in which the n+Si layer is formed on a part of the semiconductor layer 4 other than the region covered with the channel protecting film 5, may be performed after the removing process of the inorganic insulating layer 51 forming the channel protecting film 5 as described with reference to FIG. 3C. In this case, the portion of the crystalline semiconductor film 41 other than the region covered with the channel protecting film 5 is made of n+Si layer. Thereafter, instead of the crystalline semiconductor layer 41, the n+Si layer is removed by the dry etching method in the same manner as in the process of processing the crystalline semiconductor film 41 as the pattern of the semiconductor layer 4. Accordingly, the same configuration as shown in FIG. 3E is acquired.

Next, the metal film is formed by using a DC magnetron sputtering method. In the first illustrative aspect, the metal film made of chromium may be formed to the thickness of about 200 nm. The metal film is patterned into a predetermined shape by the related photolithography method and the wet etching method, thereby forming the source electrode 6 and drain electrode 7 in the display region 101, and at the same time, the wiring layer 6a in the frame region 102 is formed. That is, the source electrode 6, drain electrode 7 and wiring layer 6a are formed by the common masking processes. As a result, all of the source electrode 6, drain electrode 7 and wiring layer 6a are formed at the same layer. The source wiring 110 as shown in FIG. 1 is also formed at the same layer as the source electrode 6, drain electrode 7 and wiring layer 6a by the common masking processes (not shown in this drawing). The chromium film was wet-etched by using etching solution that is made of perchloric acid and ammonium cerium nitrate. In the region where the chromium film is etching-removed, a silicide film is formed on the surface of the semiconductor layer 4 caused by the reaction occurred by contacting the chromium film and the semiconductor layer 4. As a result, a leakage current may flow between the source electrode 6 and the drain electrode 7. Accordingly, by performing the dry etching after the wet etching of the chromium film, the silicide film formed on the surface of the semiconductor layer 4 was removed. As a result, the configuration shown in FIG. 3F is acquired.

Thereafter, the protective insulating layer 8 is formed to cover all the source electrode 6 and the drain electrode 7, which are formed in the display region 101, and the wiring layer 6a, which is formed in the frame region 102. The protective insulating layer 8 covers commonly the TFT itself, source electrode 6, drain electrode 7, wiring layer 6a and the wiring converting unit 12 itself, thereby preventing a contacting with wetness. Further, because the TFT and the wiring converting unit 12 are formed commonly, the manufacturing process is simplified. According to the first illustrative aspect, the protective insulating film 8 is formed by using a plasma CVD method, and a silicon nitride film (SiN film) is employed as a wetness proof film and formed with the enough thickness, for instance about 300 nm in thickness. Next, the contact hole 9 is formed by using the related lithography method and dry etching method. In more detail, the contact hole formed in the protective insulating film 8 is formed at the predetermined region on the drain electrode 7. As a result, the configuration shown in FIG. 3G is acquired. Next, for forming a terminal electrode including the pixel electrode 11 and an external electrode, a transparent conductor oxide film having transparency and conductivity, such as ITO and IZO, is formed and patterned by the related photolithography method. Thus, the pixel electrode 11 and terminal electrode (not shown) are formed. According to the first illustrative aspect of the present invention, the transparent conductor oxide film of amorphous film having a superior workability is formed by the sputtering method by using DC magnetron and using a mixed gas containing Ar gas, O₂ gas, and H₂ gas. Here, the pixel electrode 11 is patterned to be connecting to the drain electrode 7 through the contact hole 9. Also, the etching of the transparent conductor oxide film is performed by the wet etching method using an oxalic acid based etching-solution. Thereafter, the unnecessary photo resist is removed and is crystallized the transparent conductor oxide film of amorphous film by an anneal process. As a result, the configuration shown in FIG. 2, that is, the pixel TFT 108 arranged in the display region 101 and the wiring converting unit 12 is arranged in the frame region 102, on the TFT array substrate 100, are achieved. Also, here, the method of manufacturing the pixel TFT 108 arranged in the display region 101 was described as an example. However, the driving TFT, which is formed in the scanning signal driving circuit 103 and the scanning signal driving circuit 104, may be simultaneously formed by the manufacturing processes that are common to the microcrystalline silicon TFT used for forming the pixel TFT 108. In more detail, since it is omitted that the formation of the pixel electrode 11 and the contact hole 9 connecting the pixel electrode to the drain electrode 7 in the driving TFT, a photo mask, in which the opening or pattern of the driving TFT is omitted, is used in the photolithography method. For the other thing, the driving TFT is formed in the configuration common to the manufacturing processes of the microcrystalline silicon TFT that is used in the pixel TFT 108. As a result, the TFT array substrate 100 used in the liquid crystal display device is achieved, according to the first illustrative aspect.

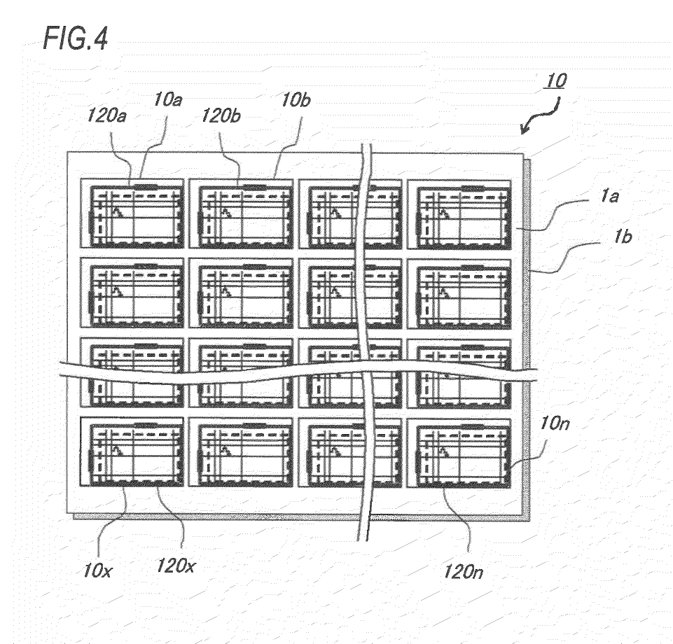

Next, the cell assembling process in the method of manufacturing the liquid display device will be described with reference to FIG. 4. FIG. 4 is a plan schematic diagram showing the configuration of the mother liquid crystal cell substrate 10 in which the liquid crystal cell substrates forming liquid crystal display panels are arranged in an array, in the manufacturing process of the liquid crystal display device according to the first illustrative aspect. Generally, in view of effectiveness in mass productivity of a small-sized liquid crystal display device, as shown in FIG. 4, the mother liquid crystal sell substrate 10 is formed in such a manner. That is, n sheets of liquid crystal cell substrates 10a, 10b, . . . , 10x, . . . , 10n are separately arranged in an array on the mother liquid crystal cell substrate 10, and each of the liquid crystal cell substrates 10a, 10b, . . . , 10x, . . . , 10n are cut into a unit size of liquid crystal display panel from the mother liquid crystal cell substrate 10. As a result, the liquid crystal display panel as shown in FIG. 1 is acquired. Accordingly, in the method of manufacturing the above-mentioned TFT array substrate 100, a plurality of TFT array substrates 100 arranged in a plurality of arrays, is manufactured as one sheet of mother TFT array substrate 1a, which is a large sized transparent insulating substrate, at a time in such method.

The mother TFT array substrate 1a, which is manufactured by the same method as the method of manufacturing the TFT array substrate 100, is formed, and the counter mother substrate 1b that is to be arranged facing the mother TFT array substrate 1a as shown in FIG. 4 is also formed. The counter mother substrate 1b may be a general substrate having color resist (colored material), black matrix (BM), and counter electrode, etc. An alignment film is formed by the related method on each of the surfaces of the mother TFT array substrate 1a and counter mother substrate 1b, thereafter, each of seals 120a, 120b, . . . , 120x, . . . , 120n surrounding a liquid crystal sealed region corresponding to each of the liquid crystal cell substrates 10a, 10b, . . . , 10x, . . . , 10n is formed on one side of the substrate. After that, the mother TFT array substrate 1a and the counter mother substrate 1b are bonded together. In this way, the mother liquid crystal cell substrate 10 shown in FIG. 4 is formed. Also, the sealing method of liquid crystal in the region surrounded by the seal may be performed by using a vacuum injection method, in which the liquid crystal is injected through an injection inlet under a vacuum state after the bonding process, or may be performed by using a liquid crystal dropping method, in which the sealing and the bonding of liquid crystal are performed at the same time after dropping liquid crystal in the region surrounded by the seal. In the case of the vacuum injection method, the process of cutting the liquid crystal cell substrate into the unit size of each of the liquid crystal display panel is performed, before sealing of the liquid crystal. In the case of the dripping method, the cutting process is performed after sealing of the liquid crystal. As a result, the cell assembling process is completed, and each of the liquid crystal cell substrates 10a, 10b, . . . , 10x, . . . , 10n are acquired.

Finally, a polarizing plate is provide on each of the liquid crystal cell substrates 10a, 10b, . . . , 10x, . . . , 10n in the each of the TFT array substrate 100 and the external side of the counter substrate. The counter substrate is cut near the external terminal of the TFT array substrate 100 so that the external terminal is exposed and an IC chip 118 or a print substrate 119 is mounted on the exposed external terminal. As a result, the liquid crystal display panel shown in FIG. 1 is achieved. Further, an optical sheet, such as a phase difference plate etc., and a backlight unit, etc., are provided on the reverse side of the TFT array substrate 100, and then, the resultant devices are housed in a casing, etc., together with the liquid crystal panel. Thus, the manufacturing of the liquid crystal display device according to the first illustrative aspect is completed.

Next, the effect of the liquid crystal display device according to the first illustrative aspect will be described. First, the TFT formed in the liquid crystal display device of the first illustrative aspect has a configuration of the channel protecting film type TFT, in which the channel protecting film 5 covering and protecting the channel region 4c is formed, thereby preventing the back side of the channel region 4c from a damage by plasma and reducing the leakage current from the back side of the channel region 4c. Further, at least the channel region has a crystalline semiconductor part, thereby improving the field effect mobility. Accordingly, a superior TFT is achieved. Further, the superior TFT is employed as a pixel TFT, which serves as a switching device in the display region, or a driving TFT, which is formed and embedded in the TFT array substrate. Thus, leakage current of the pixel TFT and a variation in display image is reduced. By improving the field effect mobility, a driving circuit mounted in the TFT array substrate, thereby reducing the number of additional external IC. Accordingly, reducing the parts and resources, a lightweight display device, a slim frame, and reducing a cost due to an improvement in productivity in the manufacturing are achieved.

In the liquid crystal display device according to the first illustrative aspect, in case that a wiring converting unit, which connects electrically the wiring layer 2a, which is formed at the same layer as the gate electrode 2, and the wiring layer 6a, which is formed at the same layer as both the source electrode 6 and the drain electrode 7, is arranged in the frame region 102, specifically arranged in the outer side of the region surrounded the seal 120, the wiring converting unit is formed in the same configuration as the wiring converting unit 12 formed in such a manner that the wiring layer 2a and the wiring layer 6a are connected directly through the contact hole 13 provided in the gate insulating film 3. Accordingly, in the wiring converting unit 12, all of the wiring layer 2a, wiring layer 6a and contact hole 13, etc., are formed at a layer lower than the protective insulating film 8, thereby not being exposed to the surface of the TFT array substrate 100. Thus, in the case that wetness is generated at the space between the color filter substrate and the TFT array substrate 100 in the outer side of the region surrounded by the seal 120 due to a dew condensation, the electric chemical reaction is not occurred between common potentials applied to the counter electrode provided on the surface of the color filter substrate. Accordingly, the breaking of wiring caused by corrosion, etc., in the frame region can be prevented. As a result, it can be prevent decreasing a yield rate due to defective products caused by the corrosion, etc., at the frame region or prevent decreasing the reliability of the manufactured liquid crystal display device. Accordingly, it can reduce the number of defective substrates during the manufacturing, thereby reducing a cost of raw materials. Further, it can achieve reducing the unnecessary processes for manufacturing normal products in replacement of defective products, thereby reducing the amount of energy waste during the manufacturing. That is, an entire cost of a product is lowered.

Also, in the wiring converting unit connecting electrically the wiring layer 2a and the wiring layer 6a that are provided in the scanning signal driving circuit 103 and the scanning signal driving circuit 104, specifically, in the interior of the driving circuit, an electro-chemical reaction is easily occurred because wirings applied different potentials are arrayed close to each other. Accordingly, in the interior of the driving circuit, this wiring converting unit formed by a configuration as the wiring converting unit 12, in which the contact hole 13 is formed in the gate insulating film 3, to connects directly the wiring layer 2a and the wiring layer 6a. Thus, the corrosion is efficiently prevented. Even in an inner side of the region surrounded by the seal 120, the same electro-chemical reaction described above may be occurred due to a small amount of wetness existing in a liquid crystal or on the alignment film between a seal and a substrate. However, since the scanning signal driving circuit 103 and scanning signal driving circuit, 104 have the same configuration as described above regardless of the inner side and outer side of the region surrounded by the seal, the same effect may be acquired in all of these parts. Meanwhile, since the wetness and the electro-chemical reaction may be easily occurred due to the dew condensation in the outer side of the region surrounded by the seal 120, specifically near the seal, it is effective using the above-described configuration having the wiring converting unit 12, in which the wiring layer 2a and the wiring layer 6a are directly connected through the contact hole 13 at the outer side of the region surrounded by the seal 120. That is, there is a higher effect in preventing the break of wiring caused by the corrosion in the wiring converting unit, and it is very effective.

Also, in the TFT provided in the liquid crystal display device according to the first illustrative aspect, the gate insulating film 3 is formed by a SiO film, which is an upper layer that is a side of the semiconductor layer 4, and the entire channel region 4c of the semiconductor layer 4 is formed by the microcrystalline silicon film. Accordingly, an interface surface between the gate insulating 3 and the crystalline semiconductor is formed by a microcrystalline silicon film and a SiO film, thereby reducing the storage capacitance in the interface and preventing variation in the threshold voltage. The same effect may be acquired even though the gate insulating film 3 is formed by a single layer of SiO film. And, at least in the portion contacting with the crystalline semiconductor part of the semiconductor layer 4, the same effect can be acquired when the crystalline semiconductor part is formed by a crystalline silicon film and the gate insulating film 3 is made of a SiO film.

Also, in the TFT provided in the liquid crystal display device according to the first aspect, a lower layer provided at a side of the semiconductor layer 4 is made of SiO film and the channel region 4c of the semiconductor layer 4 is fully formed by a microcrystalline silicon film. Accordingly, since the interface of the crystalline semiconductor part of the channel protecting film 5 is made of the microcrystalline silicon film and the SiO film, the storage capacitance at the interface may be reduced and variation in the threshold voltage may be prevented. The same effect is acquired even though the channel protecting film 5 is formed by a single layer of SiO film. In at least part contacting with the crystalline semiconductor part in the semiconductor layer 4, the same effect can be acquired when the crystalline semiconductor part is made of a crystalline silicon film and the channel protecting film 5 is made of a SiO film. Meanwhile, according to the first illustrative aspect, the channel protecting film 5 is formed by a stacked configuration that includes a SiO film as a lower layer and a SiN film as an upper layer. Thus, in addition to the effect of the formation of SiO film as a lower layer, an additional effect that reduces a peel of the crystalline semiconductor film 4 during the processing of the inorganic insulating film 51 forming the channel protecting film 5 is achieved.

Also, in the TFT provided in the liquid crystal liquid display device according to the first illustrative aspect, the channel region 4c of the semiconductor film 4 formed by a crystalline silicon film is formed by a crystalline semiconductor made of small grains having a size in approximately equal to or less than 100 nm, i.e., that is made of a microcrystalline silicon film. Accordingly, in the crystallization process of forming a crystalline semiconductor part from a amorphous semiconductor film, there are various advantages such that it is easy to manufacture the product because the optimum condition is selected from a wide range, it may prevent the crystal size from being varied, and it may reduce a variation in the TFT characteristic using the formed semiconductor film. In case of using the TFT having the crystalline semiconductor part formed by the microcrystalline silicon film, the effect of reducing the variation in the TFT characteristic has a specifically advantageous when the above TFT is used in a pixel TFT of semiconductor device functioning as a display device, because the effect of reducing the irregularity in the display is remarkably improved. However, the semiconductor film 4 is not limited to a microcrystalline silicon film. The semiconductor film 4, for instance, may be made from crystal grains that have enlarged sizes by controlling irradiation conditions, such as irradiation energy of a laser light, condition of a irradiation time, substrate temperature, etc., during the crystallization process of amorphous semiconductor film. That is, the semiconductor layer formed by the crystallization process may be a general polycrystalline semiconductor film, which is not classified into a microcrystalline silicon film. When it is a crystalline semiconductor film, there is an advantage that field effect mobility is higher than in the TFT in which a known non-crystalline semiconductor film is used in the channel region. Also, if the amorphous semiconductor film etc. is mixed in the semiconductor layer 4, holes having a high light absorption coefficient are formed in an amorphous semiconductor film during light irradiation, and then, the holes are injected into a crystalline semiconductor part which is in contact with an amorphous semiconductor film. Thus, off-current may be increased. Thus, it is preferable that the entire semiconductor layer 4 is formed by a crystalline semiconductor part that is made of a crystalline semiconductor film or microcrystalline silicon film, etc. However, at least in the channel region 4c, when the semiconductor layer 4 has the crystalline semiconductor part, it can acquire the field effect mobility higher than the TFT in which a non crystalline semiconductor film is used in a channel region, and the same effect can be acquired by using the TFT having array substrate including the driving circuit according to the first illustrative aspect. Regarding the kind of semiconductor, silicon has been described as an example, if a microcrystalline or crystalline semiconductor can be formed. However, a semiconductor using different elements other than the above-described elements can be used.

Further, a liquid crystal display device has been described as an example of a semiconductor device using a TFT according to the first illustrative aspect. However, the semiconductor device using the TFT according to the first illustrative aspect can also be applied to a flat type display device (flat panel display), such as an organic EL display device etc., which is a display device other than the liquid crystal display device, or a photoelectric conversion device, such as an image sensor etc., of a semiconductor device other than the display device. For example, in the case of organic EL display device, the organic EL display device is only modified in a manner that voltage for displaying is applied to an electric optical material, such as a self emission material etc., by the pixel electrode 11 of the liquid crystal display device according to the first illustrative aspect of the present invention. Thus, a color substrate or the seal 120 may be omitted in the configuration of the organic EL display. In the case of the organic EL display device, a counter electrode is not formed on a surface of a color filter substrate. Further, in the case of a general semiconductor device other than the display device, a region exposed to air similar to the region surrounded by the seal 120 of the liquid crystal display device is not existing. However, in the above case of a driving circuit of the driving circuit embedded semiconductor devices, the each wirings applied with different potentials in a driving circuit are arrayed close to each other, so that the same problems as described in the foregoing are occurred. Accordingly, the present invention can be applied in the same manner and achieve the same effect. Even in the case of the driving circuit embedded semiconductor device, the same TFT array substrate 100 as the first illustrative aspect is formed, and then, all the wiring converting unit, which connects between the wiring layer 2a formed at the same layer as the gate electrode 2 in a driving circuit of the frame region 102 and the wiring layer 6a formed at the same layer as both the source electrode 6 and the drain electrode 7, may be configured in the same configuration as the wiring converting unit 12, which directly connects the wiring layer 2a and the wiring layer 6a through the contact hole 13 formed in the gate insulating layer 3. Accordingly, similar to the liquid crystal display device according to the first illustrative aspect, it can achieve the effect of preventing a reduction in the yield or the reliability caused by the corrosion etc. in the frame region. At least in the interior of the driving circuit of semiconductor device including a thin film transistor substrate having a TFT and a driving circuit, if it includes the wiring converting unit 12 that connects electrically and directly the wiring layer 2a as first wiring layer, which is formed at the same layer as a gate electrode, and the wiring layer 6a as second wiring layer, which is formed at the same layer as both a source electrode and a drain electrode through the contact hole 13 formed in the gate insulating film 3, it achieve the effect of preventing a corrosion in the wiring converting unit between the wiring layer 2a and the wiring layer 6a. Accordingly, it can achieve the same effect as in the first illustrative aspect described above. In addition, even in the effect of the configuration of the driving TFT or the pixel TFT, in a semiconductor device including a thin film transistor substrate having the TFT and the driving circuit, the configuration of the pixel TFT and the driving TFT according to the first illustrative aspect of the present invention is applied together with the configuration of the wiring converting unit 12. Thus, the same effect as in the first illustrative aspect is achieved. Meanwhile, since the first illustrative aspect is a liquid crystal display device having the counter electrode provided on the counter substrate, each wiring applied different potentials in a driving circuit are arranged close to each other, and further the counter electrode has a distance of a substrate spacing, relatively close to a wiring converting unit. Thus, electric chemical reaction is easily occurred. In addition, current path is appeared near the seal through impurities attached to a seal sidewall regardless of the interior or exterior of the region surrounded by the seal. Thus, the electric chemical reaction is accelerated by a minute amount of current flowing through a surface of the seal sidewall. Accordingly, the above-mentioned configuration in a driving circuit of a liquid crystal display device, specifically near the seal, is very effective since it prevents wirings from the breaking due to the corrosion in a wiring converting unit.

### (Second Illustrative Aspect)

In the first illustrative aspect of the present invention, the liquid crystal device has a channel protecting film type TFT structure including the channel protecting film 5, the liquid crystal display device includes the wiring converting unit 12 that directly connects the wiring layer 2a, which is formed at the same layer as the gate electrode 2, and the wiring layer 6a, which is formed at the same layer as both the source electrode 6 and the drain electrode 7, through the contact hole 13. As described above, the liquid crystal display device according to the first illustrative aspect is possible to achieve many effects. However, in the first illustrative aspect, since a general method of manufacturing the liquid crystal display device is described as an example, a masking process for forming the channel protecting film 5 is increased compared with using the back channel etching type TFT structure. Also, the contact hole 13 of the wiring converting unit 12 is not formed by a process in common with the masking process of forming the contact hole 9 for connecting the pixel electrode 11 to the drain electrode 7, thus a masking process is increased. That is, in view of a manufacturing process, the first illustrative aspect has not been optimized as the best. Meanwhile, in the liquid crystal display device according to the first illustrative aspect, the semiconductor layer is formed in a region other than the contact hole 13 as an opening formed in the gate insulating film 3, and the channel protecting film 5 is formed in the region in which the semiconductor layer is formed. In other words, in view of a top plan view, in the patterns of the gate insulating layer 3, the semiconductor layer 4 and the channel protecting film 5, the latter pattern is included to the former pattern in that order. In such configuration, it is possible to commonalize a masking process by using a related halftone mask having a halftone exposure region. That is, since the configuration of the present invention is optimized to using the halftone mask, it is possible to reduce easily the number of masking processes. Next, it will be described a method of manufacturing the liquid crystal display device according to the second illustrative aspect in which one masking process is decreased from the manufacturing method according to the first illustrative aspect. The method of manufacturing the second illustrative aspect is only different in the formation process of the channel protecting film 5 and the contact hole 13 from the method of manufacturing the first illustrative aspect, the configuration of the liquid crystal display device and the other processes of the manufacturing method is the same as the first and second illustrative aspects. Accordingly, hereinafter, the processes for forming the channel protecting film 5 and the contact hole 13 which are different from the first illustrative aspect will be described in detail. The configuration and method of manufacturing the liquid crystal display device having the same configuration as in the first illustrative aspect will be omitted.

In the first illustrative aspect as described with reference to FIG. 3B, the gate insulating film 3, the crystalline semiconductor film 41 of semiconductor film having crystalline characteristics and the inorganic insulating film 51 that is to be the channel protecting film 5 were formed. Thereafter, to connect the wiring layer 2a and the wiring layer 6a of the frame region 102, the gate insulating film 3 on the wiring layer 2a, the crystalline semiconductor film 41 and the inorganic insulating film 51 that is to be the channel protecting film 5 were removed, and then, the contact hole 13 formed in the gate insulating film 3 was formed. Thereafter, the inorganic insulating film 51 was additionally patterned in a predetermined shape by using the related photolithography method and dry etching method and the channel protecting film 5 is formed. On the other hand, in the second illustrative aspect, however, the contact hole 13 formed in the gate insulating film 3 and the channel protecting film 5 are formed during only one masking process, that is a lithography process, by using the related halftone mask. Hereinafter, an example of the forming processes of the contact hole 13 and the channel protecting film 5 by using the halftone mask will be described in detail.

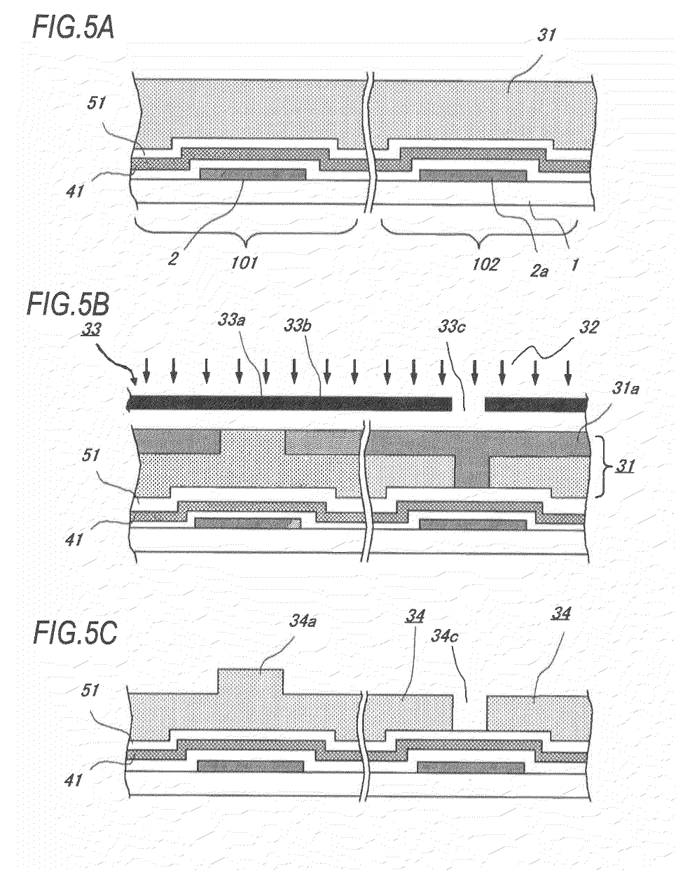

First, as shown in FIG. 5A, the gate insulating film 3, the crystalline semiconductor film 41 having crystalline characteristics, and the inorganic insulating film 51 that is to be the channel protecting film 5, and then, photo resist 31 is formed over the gate insulating 3 are formed on the transparent insulating substrate 1 including the gate electrode 2 formed in the display region 101 and the wiring layer 2a formed in the frame region 102. Since the above configuration in the second illustrative aspect is similar to the first illustrative aspect, the detailed manufacturing method as related will be omitted. Next, as shown in FIG. 5B, the photo resist 31 on the inorganic insulating film 51 is performed the exposing 32 by using the related halftone mask 33. In this way, the exposure process is performed with the exposure light having three-leveled intensities different from one another in response to regions. Hereinafter, the configuration of halftone mask 33 according to the second illustrative aspect will be described in detail.

The halftone mask 33 according to the second illustrative aspect includes a first light transmission region 33a, a second light transmission region 33b and a third light transmission region 33c, and, at least one of which is a halftone exposure region. Herein, the second light transmission region 33b is the halftone exposure region, and it has the middle light transmittance between the transmittances of the first light transmission region 33a and the third light transmission region 33c. Concretely, a halftone exposure region may be configured by a film having a certain light transmittance or a light-shielding film having a fine pattern finer than an exposure resolution for decreasing the practical light transmittance. Herein, the first light transmission region 33a is formed by s light-shielding region, which does not transmit the light at all. Meanwhile, the first light transmission region may have light transmittance lower than the second light transmission region 33b and may transmit the light a little. In contrast, the third light transmission region 33c is formed by an opening region, which transmits the light almost. Meanwhile, the third light transmission region may have light transmittance higher than the second light transmission region 33b and it may cut the light a little.

By performing the exposing 32 through the halftone mask 33, a photo resist 31 is irradiated with the exposure light having the three-leveled intensities, that is, the three-leveled exposed amount. By the exposure using the exposure light having the three-leveled different amount or the three-leveled different intensities, since the depth or the degree of exposure in the photo resist 31 is different in response to the intensity or the amount of exposure light in exposing, an exposure region 31a that is different in the depth or the degree of exposure is formed in each of the regions. Herein, the thickness in the exposure region 31a is changed as shown in FIG. 5B. However, the exposed degree of the photo resist 31 is changed in response to the intensity of exposure light or the amount of exposure light, but the depth of the exposure region 31a to be exposed may not be changed. That is, the thickness of the exposure region 31a only illustrates an example of the exposed degree. Accordingly, the depth descried above does not illustrate the actually exposed depth, but it may be read as the exposed degree. In the second illustrative aspect of the present invention, since a positive type photo resist is used, the exposure region 31a is formed thick or the progress degree of exposure is formed great in the region, in which the intensity of exposure light or the amount of exposure light is great, in response to the intensity of exposure light or the amount of exposure light. Also, when the developing process, which will be described later, of a predetermined condition is performed, the greater the intensity of exposure light or the amount of exposure light, the greater the removed thickness of the exposure region 31a in response to the depth of the exposure region 31a or the exposed degree of the exposure region 31a, the thinner the thickness of the photo resist film after the developing process. Herein, in the region corresponding to the first light transmission region 33a, the exposure region 31a is not formed. In the second light transmission region 33b, the exposure region 31a is formed in a part of the photo resist 31 in the thickness direction of the photo resist 31. In the region corresponding to the third light transmission region 33c, the exposure region 31a is formed throughout the total thickness of the photo resist 31. Since the first light transmission region 33a may have a light transmittance property, even in the region corresponding to the first light transmission region 33a, the exposure region 31a may be formed to have a thickness thinner than the second light transmission region 33b. Also, the first light transmission region 33a corresponds to the region that forms the channel protecting film 5, the third light transmission region 33c corresponds to the region that forms the contact hole 13 formed in the gate insulating film 3. The second light transmission region 33b corresponds to the other region in which the gate insulating film 3 remains. After the exposure region 31a is formed in above process, the exposure region 31a is removed in the developing process. As a result, as shown in FIG. 5C, it is formed the photo resist 34 including the thick film part 34a located at the region where the channel protecting film 5 is to be formed and the opening 34c in the region where the contact hole is to be formed.

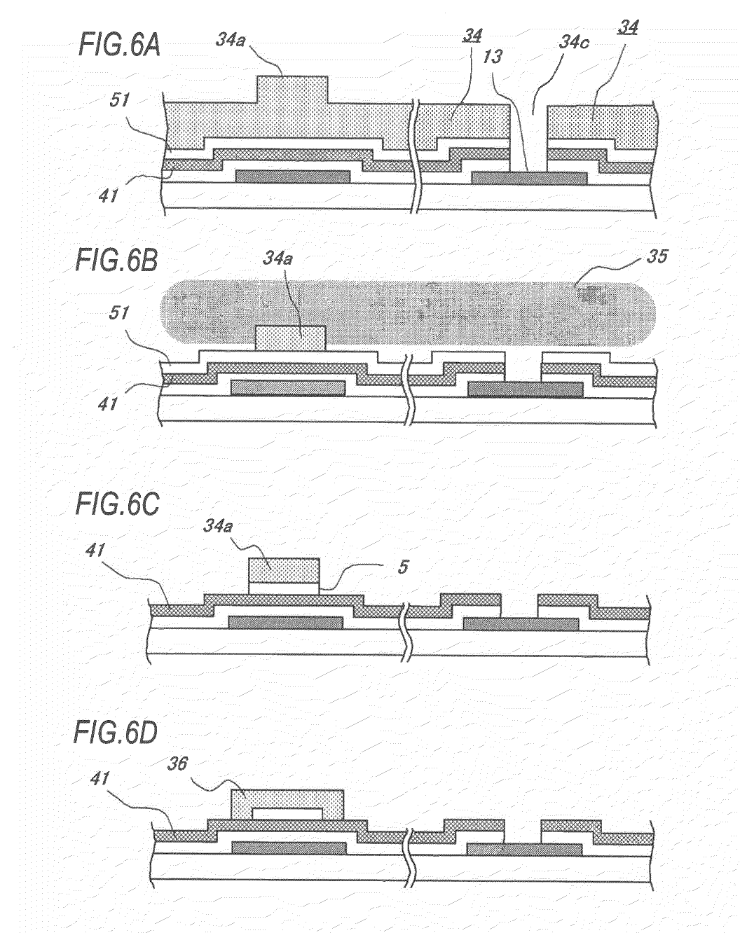

Next, in the opening 34c of the photo resist 34 formed by the above-described method, the gate insulating film 3 on the wiring layer 2a, the crystalline semiconductor film 41 and the inorganic insulating film 51 that is to be the channel protecting film 5 are removed by performing a dry etching processing. As a result, the contact hole 13 formed in the gate insulating film 3 is formed in the predetermined region on the wiring layer 2a. By the above-processes, the configuration as shown in FIG. 6A is acquired. Next, the process for reducing the thickness of the photo resist 34 is performed by the ashing processing 35 in which a plasma processing is performed using O₂ gas. Thus, the photo resist 34 is removed while leaving the thick film part 34a having a thick part. The remained thick film part 34a in the photo resist 34 is corresponding to the region to be formed the channel protecting film 5. By the above-described processes, the configuration shown in FIG. 6B is acquired. Preferably, the ashing time is predetermined. In this case, by estimating the thickness of both the thick film part 34a having a thick part and the film thickness other than the thick film part 34a in the photo resist 34, the ashing time may be set between a time period in which the photo resist 34 other than the thick film part 34a is all removed and a time period in which the thick film part 34a is etched. Meanwhile, after the photo resist 34 on the surface of the inorganic insulating film 51 to be the channel protecting film 5 is removed, by monitoring the luminescence occurring when the inorganic insulating film 51 is exposed to the plasma of the ashing, the ashing time may be set during the processing.

Next, the inorganic insulating film 51 is removed by the dry etching method using the remained photo resist 34 in the thick film part 34a as a mask, thereby forming the channel protecting film 5. As a result, the configuration shown in FIG. 6C is acquired. The processing of removing the inorganic insulating film 51 using the dry etching method may be the same in the first illustrative aspect, thus, the detailed explanation will be omitted. Thereafter, the photo resist 36 is formed by the related photolithography method in the region to be formed the semiconductor layer 4 by the same method in the first illustrative aspect. Thus, the configuration shown in FIG. 6D is acquired. Further, the crystalline semiconductor film 41 is removed by the dry etching method using the photo resist 36 as a mask, thereby forming a predetermined pattern and forming the semiconductor layer 4. As a result, the configuration as shown in FIG. 3D illustrated in the first illustrative aspect is acquired. Hereinafter, the other processing may be the same manufacturing processes in the first illustrative aspect. Thus, the detailed explanation will be omitted.

As a result of the method of manufacturing the liquid crystal display device according to the second illustrative aspect, the masking process, which forms the channel protecting film 5, and the masking process, which forms the contact hole 13 configuring the wiring converting unit 12 that directly connects the wiring layer 2a formed at the same layer as the gate electrode 2 and the wiring layer 6a formed at the same layer as both the source electrode 6 and the drain electrode 7, may be commonalized, and the configuration is formed by single photolithography process. It can achieve the same effect in the first illustrative aspect, and, at the same time, the number of masking processes can be reduced, thereby improving the productivity. In addition, the electric power consumption and other energy, photo resist, development solution, and raw material cost, etc., in the manufacturing can be reduced.

### (Third Illustrative Aspect)

According to the second illustrative aspect, it is described that the method for commonalizing photolithography processes and reducing one process from the method of manufacturing the first illustrative aspect, in the masking process, which forms the channel protecting film 5, and the masking process, which forms the contact hole 13 configuring the wiring converting unit 12 that directly connects the wiring layer 2a formed at the same layer as the gate electrode 2 and the wiring layer 6a formed at the same layer as both the source electrode 6 and the drain electrode 7. Next, it will be described the other method of reducing one process in the method of manufacturing the liquid crystal display device according to the third illustrative aspect. The method according to the third illustrative aspect is only different in the forming processes of the channel protecting film 5, the semiconductor layer 4 and the contact hole 13 from the method of the second illustrative aspect. The configuration of the liquid crystal display device and the other processes in the method of manufacturing the liquid crystal display device other than the above forming processes is similar to the configuration and the method of the second illustrative aspect. Accordingly, hereinafter, the forming processes of the channel protecting film 5, the semiconductor layer 4 and contact hole 13 will be described in detail and the configuration and the method of manufacturing the liquid crystal display device, which are similar to the second illustrative aspect, will be omitted.

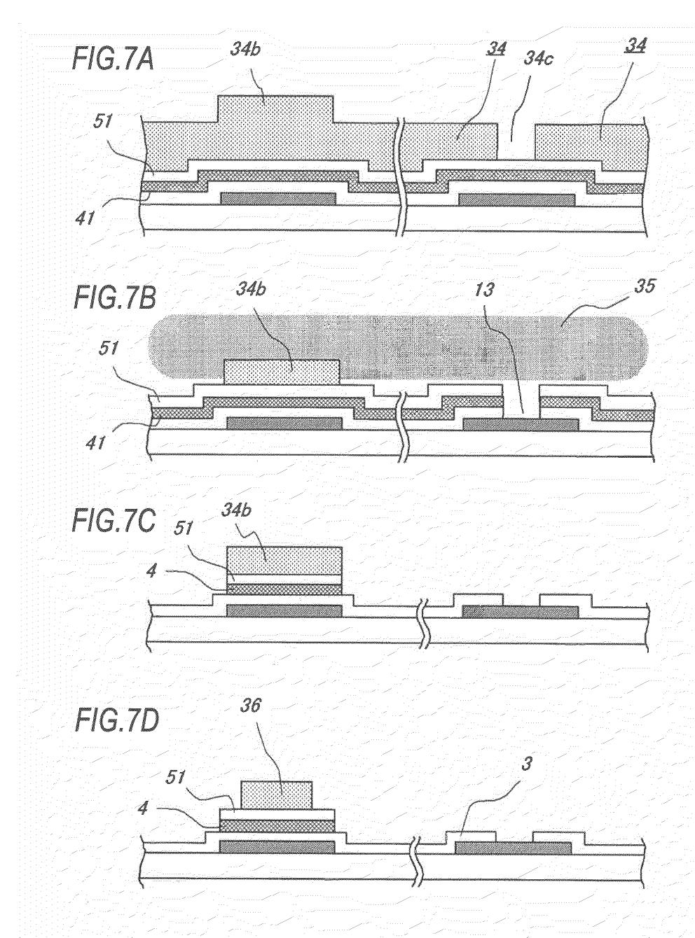

First, as shown in FIG. 7A, which is similar to FIG. 5C in the second illustrative aspect, according to the third illustrative aspect, the gate insulating film 3, the crystalline semiconductor film 41 of semiconductor film having a crystalline property, and the channel protecting film 5, and the inorganic insulating film 51 that is to be the channel protecting film 5 are formed on the transparent insulating substrate 1, which includes both the gate electrode 2 formed in the display region 101 and the wiring layer 2a formed in the frame region 102. Thereafter, the photo resist 34 including both the thick film part 34b located at the region where the semiconductor layer 4 on the gate insulating film 3 is to be formed and the opening 34c located at the region where the contact hole 13 is to be formed. According to the second illustrative aspect, the thick film part 34a located the region corresponding to the region where the channel protecting film 5 is to be formed. However, as the difference from the second illustrative aspect, according the third illustrative aspect, it is only different in that the thick film part 34b is formed in the region corresponding to the region to be formed the semiconductor layer 4. Accordingly, the third illustrative aspect is similar to the second illustrative aspect in the process of performing the exposure processing with the exposure light having the three-leveled different intensities according to its regions by using the above described halftone mask 33 in the second illustrative aspect, and only the first light transmission region 33a of the halftone mask 33 may be replaced with the region corresponding to the region to be formed the semiconductor layer 4.

Next, the gate insulating film 3, the crystalline semiconductor film 41 and the inorganic insulating film 51 to be the channel protecting film 5 on the wiring layer 2a in the opening 34c of the photo resist 34 are removed by performing the dry etching processing. As a result, the contact hole 13 formed in the gate insulating film 3 is formed in a predetermined region on the wiring layer 2a. Next, a part of the photo resist 34 other than the thick film part 34b is removed by performing the thickness reducing process for cutting the photo resist 34 by means of the aching processing 35 using the plasma processing using O₂ gas. The thick film part 34b remains as the remained photo resist 34 in the region to be formed the semiconductor layer 4. According to the above-described processes, the configuration shown in FIG. 7B is acquired. Next, both the inorganic insulating film 51 and the crystalline semiconductor film 41 are removed by the dry etching method using the remained photo resist 34 in the thick film part 34b of as a mask, thereby acquiring the semiconductor layer 4 and the inorganic insulating film 51 which is formed to the same pattern as the semiconductor layer 4. As a result, the configuration shown in FIG. 7C is acquired. Thereafter, the photo resist 36 is formed by the related photolithography method in the region corresponding to the region to be formed the channel protecting film 5, similar to the first illustrative aspect, thereby the configuration shown in FIG. 7D is acquired. Also, the inorganic insulating film 51 formed into the same pattern as the semiconductor layer 4 is removed by the dry etching method using the photo resist 36 as a mask, thereby forming the predetermined pattern and the channel protecting film 5. Since the removing processing of the inorganic insulating film 51 by the dry etching method is similar to the first illustrative aspect, the detailed description was omitted. As seen from FIG. 7D, however, this removing processing differ in the exposed state in which the gate insulating film 3 other than the region covered with the semiconductor layer 4 and the inorganic insulating film 51 formed into the same pattern is processed. Accordingly, this removing processing is differ in that a surface of the gate insulating film 3 is also etched by the dry etching method for removing the inorganic insulating film 51. Accordingly, in the third illustrative aspect, it is preferable that the inorganic insulating film 51 is formed thin to reduce the decrement amount of the exposed gate insulating film 3 compared with in the first illustrative aspect or the second illustrative aspect. Meanwhile, in the third illustrative aspect, the gate insulating film 3 is formed by a stack film configured by a lower layer, which is a SiN film, and an upper layer, which is a SiO film, in a method similar to the first or second illustrative aspects. Accordingly, it can reduce the decrement of the gate insulating film 3 by the dry etching processing to remove the SiO film configuring the inorganic insulating film 51, compared with a case that the gate insulating film 3 all is formed by a SiN film. As a result of the removing processing of the inorganic insulating film 51, the configuration shown in FIG. 3D according to the first illustrative aspect is acquired. Hereinafter, since the manufacturing method according to the third illustrative aspect is similar to the first illustrative aspect, the detailed explanation will be omitted.

According to the method of manufacturing the liquid crystal display device according to the third illustrative aspect, in the masking process, which forms the semiconductor layer 4, and the masking process, which forms the contact hole 13 configuring the wiring converting unit 12 that directly connects the wiring layer 2a formed at the same layer as the gate electrode 2 and the wiring layer 6a formed at the same layer as both the source electrode 6 and the drain electrode 7, the above two masking processes is commonalized, it is formed one photolithography process. Accordingly, the same effect as in the first illustrative aspect is achieved, and, at the same time, the number of masking processes may be reduced, thereby improving the productivity, etc., and achieving the same effect as the second illustrative aspect.

Further, by a little modification of the method of manufacturing the liquid crystal display device in the above described third illustrative aspect, it is possible to commonalize the masking process, which forms the channel protecting film 5, and the masking process, which forms the semiconductor layer 4, and it is possible to reduce the number of masking processes by one process or more. Hereinafter, an illustrative modification of the third illustrative aspect, which reduces the number of the masking processes by one process, will be described. The process for forming the channel protecting film 5, which will be modified from the third illustrative aspect, and the processing after the formation of both the source electrode 6 and the drain electrode 7 will be described in detail, and the explanation of the manufacturing processes similar to the third illustrative aspect will be omitted.

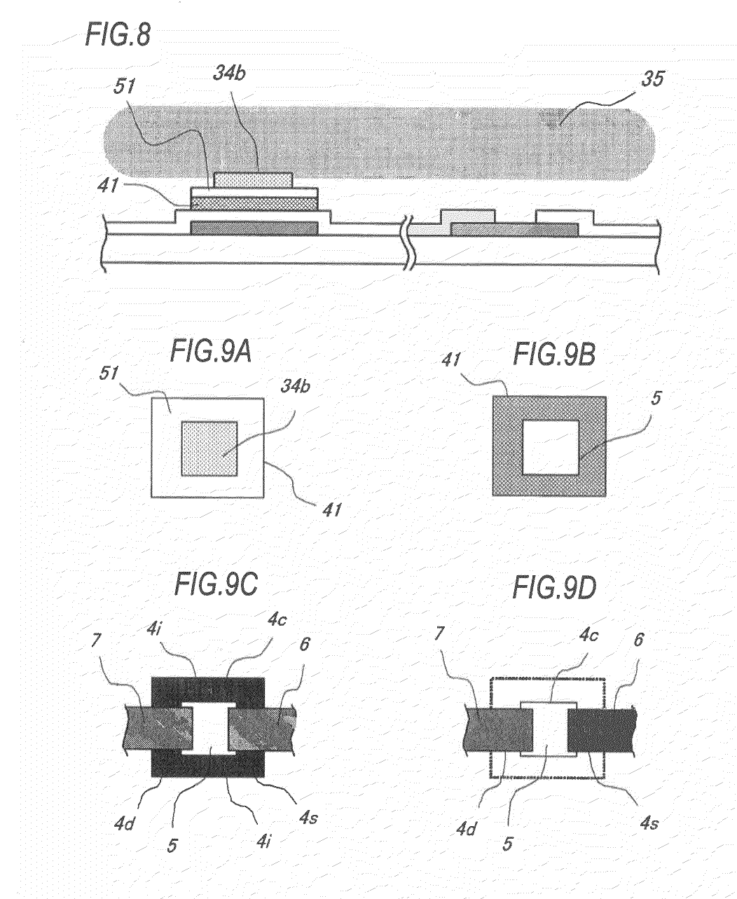

According to the illustrative modification of the third illustrative aspect, first, the method of manufacturing the third illustrative aspect will be described with reference to FIG. 7C. The inorganic insulating film and the crystalline semiconductor film 41 are removed by the dry etching method using the photo resist 34 in the thick film part 34b as a mask, and the semiconductor 4 and the inorganic insulating film 51 are formed into the same pattern as the semiconductor layer 4. Next, as shown in FIG. 8, it is performed the process of reducing the thickness in which the thick film part 34b of the remained photo resist 34 is cut in the region corresponding to the region to be formed the semiconductor layer 4 by the ashing processing of plasma using O₂ gas. As a result, the thickness of the thick film part 34b is reduced and, at the same time, the end-face of the pattern of the thick film part 34b is set back. That is, as shown in the plan schematic diagram view of TFT portion in FIG. 9A, even in the plane pattern, the pattern end-face of the thick film part 34b is approximately set back in isotropic, and the area of the region covered with the thick film part 34b is reduced. In this way, by performing the set back processes for set back the pattern end-face of the thick film part 34b, the region covered with the thick film part 34b is reduced and the thick film part 34b is removed other than the region where the channel protecting film 5 is to be formed. As shown in the cross sectional view of FIG. 8 or the plan view of FIG. 9A, the surface of the inorganic insulating film 51 covered with the thick film part 34b in FIG. 7C is exposed. As shown in the cross sectional view of FIG. 7C, even in the plan view of FIG. 9A, the crystalline semiconductor film 41 formed in the same shape pattern under the inorganic insulating film 51 is formed. Reducing the region, and the inorganic insulating film 51 outside the region covered with the thick film part 34b is removed by the dry etching method using the remained thick film part 34b remained in the region corresponding to the region to be formed the channel protecting film 5. Thus, the channel protecting film 5 is formed. The processing for removing the inorganic insulating film 51 by the dry etching method is similar to the third illustrative aspect and will not be described. In this way, the channel protecting film 5 is formed and the surface of the crystalline semiconductor film 41 is exposed at the region in which the inorganic insulating film 51 was removed. In the cross sectional view, although a little difference in the shape of the channel protecting film 5 is seemed, the configuration is approximately same to that shown in FIG. 3D of the first illustrative aspect. Consequently, the ion doping process that is applied to a region of semiconductor layer 4 outside the region covered with the channel protecting film 5 for forming the n+Si layer, which is ohmic contact layer described in the first illustrative aspect, and the processes for forming the source electrode 6, drain electrode 7 and wiring layer 6a are performed in that order. Thus, the configuration similar to the cross sectional view of FIG. 3F according to the first illustrative aspect is acquired, and the configuration shown in FIG. 9C is acquired as the plan view. As shown in FIG. 9C, the n+Si layer, which is ohmic contact layer, is formed in the crystalline semiconductor film 41 outside the region covered with the channel protecting film 5, the source region 4s and the drain region 4d are respectively formed under the source electrode 6 and the drain electrode 7 in a similar way to the first illustrative aspect. However, in the illustrative modification, the impurity semiconductor region 4i formed by the n+Si layer, which is conductive layer, is formed even between the source region 4s and the drain region 4d, and the source 4s and the drain region 4d are connected through a conductive layer. Accordingly, since the configuration as shown in FIG. 9C does not serve as a TFT, the illustrative modification needs the processes for removing the impurity semiconductor region 4i and separating the source region 4s and the drain region 4d. As a detailed processing, the dry etching processing is performed for removing the silicide film on the surface of the semiconductor layer 4 described in the first illustrative aspect, and the dry etching processing is performed for processing and removing the n+Si layer that was described in the first illustrative aspect. Accordingly, as shown in the plan schematic view of FIG. 9D, the n+Si layer, i.e. impurity semiconductor region 4i, outside the region covered with the source electrode 6, drain electrode 7 and channel protecting film 5 is removed. The region in which the impurity semiconductor region 4i was removed is surrounded by dot line in the FIG. 9D. Thereafter, since the other processing is similar to the third illustrative aspect, the explanation will be omitted.

In the illustrative modification of the third illustrative aspect as described in the above, the photo resist is used as a mask for forming the pattern of semiconductor layer 4. In this modification, by performing the end-face set back process for setting back the pattern end-face and using the modified mask for forming the channel protecting film 5, the masking process, which forms the channel protecting film 5, and the masking process, which forms the semiconductor layer 4, can be commonalized. As a result, it can be reduced the number of masking processes by one process more process from the method of manufacturing the second or third illustrative aspect. Although the number of masking processes is reduced, it requires the additional ashing process for reducing the area of the thick film part 34b or the additional dry etching process for removing the n+Si layer and separating the source region 4s and the drain region 4d. However, since such additional processes do not affect badly the productivity or manufacturing cost compared with the photolithography method, the total productivity is improved and the manufacturing cost is reduced. Accordingly, according to the illustrative modification, in addition to the third illustrative aspect, it can be acquired more improved productivity. Meanwhile, it can be used the related halftone mask similar to the second or third illustrative aspect in which the exposure process is performed with the exposure light having the three-leveled different intensities according to each of the regions. Thus, it is possible to achieve such improved productivity, etc., with easily.

### (Fourth Illustrative Aspect)

According to the second and third illustrative aspects, it was described the method of reducing the masking processes by one process from the method of manufacturing the first illustrative aspect. One process is commonalized in the masking process, which forms the channel protecting film 5 or the semiconductor film 4, and the masking process, which forms the contact hole 13 forming the wiring converting unit 12 that directly connects the wiring layer 2a formed at the same layer as the gate electrode 2 and the wiring layer 6a formed at the same layer as both the source electrode 6 and the drain electrode 7. Also, in a described method in the illustrative modification of third aspect, one process are commonalize in the masking process, which forms the channel protecting film 5, and the masking process, which forms the semiconductor film 4, thereby reducing the number of masking processes by one process. Herein, it will be described a method of manufacturing the liquid crystal display device according to the fourth illustrative aspect which reduces one process in the masking process, which forms the channel protecting film 5, and the masking process, which forms the channel protecting film 5. The method according to the fourth illustrative aspect is only different in the forming processes of the channel protecting film 5, semiconductor layer 4 and contact hole 13 from the method of the second or third illustrative aspect. The configuration of the liquid crystal display device and the other processes in the method of manufacturing the liquid crystal display device except for the above processes is similar to the configuration and method of the second or third illustrative aspect. Accordingly, the forming processes of the channel protecting film 5, semiconductor layer 4 and contact hole 13 which are modified from the second or third illustrative aspect will be described in detail and the configuration and method of manufacturing the liquid crystal display device, which are similar to the first, or second or third illustrative aspect, will be omitted.

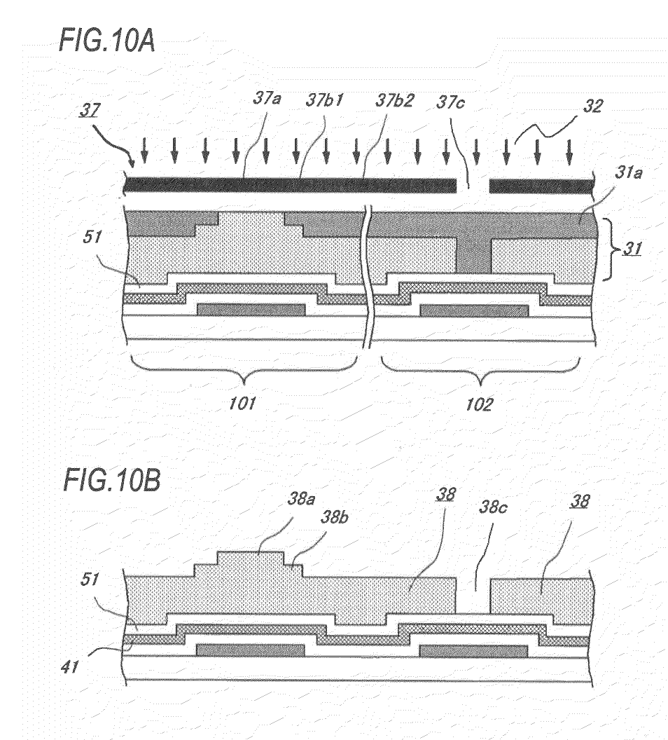

First, as shown in FIG. 5A described in the second illustrative aspect, the gate insulating film 3, the crystalline semiconductor film 41 of semiconductor film having crystalline characteristics and the inorganic insulating film 51 that is to be the channel protecting film 5 is formed on the transparent insulating substrate 1 including the gate electrode 2 formed in the display region 101 and the wiring layer 2a formed in the frame region 102. And then, photo resist 31 is formed over the gate insulating 3. Since above method in the fourth illustrative aspect is similar to the first, second, or third illustrative aspect, the detailed description of the manufacturing method will be omitted. Next, as shown in FIG. 10A, the photo resist 31 on the inorganic insulating film 51 is exposed through the related halftone mask 37 in the fourth illustrative aspect. At this time, the exposure process is performed with the exposure light having the four-leveled different intensities according to applied regions. Hereinafter, the configuration of halftone mask 37 according to the fourth illustrative aspect will be described in detail.

The halftone mask 37 according to the fourth illustrative aspect includes a first light transmission region 37a, a second light transmission region 37b1, a third light transmission region 37b2 and fourth light transmission region 37c. Here, the first light transmission region 37a is a light-shielding region, which does not transmit the light at all. Additionally, the first light transmission region 37a may have a region having the light transmittance lower than at least the second light transmission region 37b1. On the contrary, the fourth light transmission region 37c is an opening region that transmits the light almost. Additionally, the fourth light transmission region 37c may have a region having the light transmittance higher than at least the third light transmission region 37b2. The second light transmission region 37b1 and the third light transmission region 37b2 are halftone exposure regions, and they may have a middle light-transmittance between the first light transmission region 37a and the fourth light transmission region 37c. Also, the second light transmission region 37b1 may have a region having the light transmittance lower than at least the third light transmission region 37b2. Additionally, each the second light transmission region 37b1 and the third light transmission region 37b2 may be configured by different films having certain light transmittances. Also, each the second light transmission region 37b1 and the third light transmission region 37b2 may be formed by light-shielding films having different fine patterns finer than exposure resolution for decreasing the practical light transmittance. Thus, different exposure resolutions are achieved, respectively.

By performing the exposure processing 32 through such halftone mask 37, the photo resist 31 is exposed by the exposure light by the four-leveled different intensities, and the exposed depth of the photo resist 31 becomes different in response to the intensity of exposure light, thereby forming the exposure region 31a which includes the regions different in the exposure thickness. Herein, the exposure region 31a is not formed in the region corresponding to the first light transmission region 37a. In the second light transmission region 37b1, the exposure region 31a is formed at a part of the region in the thickness direction of the photo resist 31. And, in the third light transmission region 37b2, the exposure region 31a is formed thicker than in the second light transmission region 37b1. Further, in the region corresponding to the fourth light transmission region 37c, the exposure region 31a is formed throughout the total thickness of the photo resist 31. As described in the second illustrative aspect, since the first light transmission region 37a may have a light transmittance, even in the region corresponding to the first light transmission region 37a, the exposure region 31a may be formed thinner than in the second light transmission region 37b1. Also, the first light transmission region 37a corresponds to the region for forming the channel protecting film 5, the second light transmission region 37b1 corresponds to the region for forming the semiconductor layer 4, and the fourth light transmission region 37c corresponds to the region for forming the contact hole 13 formed in the gate insulating film 3 on the wiring layer 2a formed in the frame region 102. The third light transmission region 37b2 corresponds to the other region in which the gate insulating layer 3 remains. Consequently, by the developing processing, the exposure region 31a exposed to light and photo-sensed is removed as shown in FIG. 10B. As a result, it is formed the first thick film part 38b located the region where the semiconductor layer 4 is to be formed, the second thick film part 38a, which is thicker than the first thick film part 38b, located at the region the channel protecting film 5 is to be formed, and the photo resist 38 having the opening 38c located at the region where the contact hole 13 is to be formed.

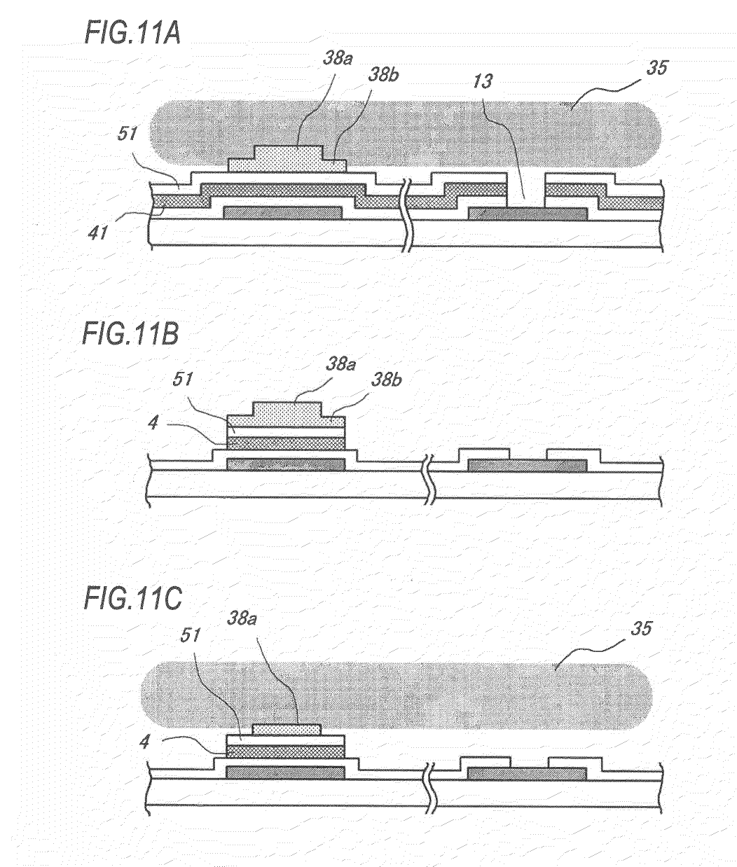

Next, by performing the etching processing through the photo resist 38 formed as described above, in the opening 38c of the photo resist 38, the gate insulating film 3 on the wiring layer 2a, the crystalline semiconductor film 41 and the inorganic insulating film 51 that is to be used the channel protecting film 5 are removed. As a result, in a predetermined region on the wiring layer 2a, the contact hole 13 opening the gate insulating film 3 is formed. Next, the thickness of the photo resist 38 is reduced by the ashing processing 35 using O2 plasma gas in a thickness reducing process, thereby removing the photo resist 38 while leaving the thick film part 38a and the thick film part 38b. The thick film part 38a and the thick film part 38b in the remained photo resist 38 remain at the region corresponding to the region to be formed the semiconductor layer 4. As a result, the configuration as shown in FIG. 11A is acquired. Next, the inorganic insulating film 51 and the crystalline semiconductor film 41 are removed by the dry etching method using the thick film part 38a and the thick film part 38b in the remained photo resist 38 as a mask. Thus, the semiconductor layer 4 and the inorganic insulating film 51 formed in the same pattern as the semiconductor layer 4 is acquired. As a result, the configuration shown in FIG. 11B is acquired. Consequently, the thickness of the photo resist 38 is reduced by the ashing processing 35 using O2 plasma gas in the thickness reducing process, thereby removing the thick film part 38b in the photo resist 38 while leaving the thick film part 38a. The thick film part 38a in the remained photo resist 38 remains at the region corresponding to a region to be formed the channel protecting film 5. As a result, the configuration as shown in FIG. 11C is acquired. Further, the inorganic insulating film 51f formed in the same pattern as the semiconductor layer 4 is removed by the dry etching method using the thick film part 38a in the remained photo resist 38 as a mask, thereby forming the channel protecting film 5. The processing of removing the inorganic insulating film 51 by using the dry etching method is similar to the third illustrative aspect, and a detailed description will not be described. As a result, the configuration shown in FIG. 3D as described according to the first illustrative aspect is acquired. The following processes are the same manufacturing processes as in the first illustrative aspect, a detailed description will not be described.

According to the method of manufacturing the liquid crystal display device in the fourth illustrative aspect as described above, the photolithography process is commonalized in the masking process forming the semiconductor layer 4, the masking process forming the channel protecting film 5, and the masking process for the contact hole 13 forming the wiring converting unit 12 that connects directly the wiring layer 2a formed at the same layer as the gate electrode 2 and the wiring layer 6a formed at the same layer as both the source electrode 6 and the drain electrode 7. Thus, the configuration is formed by single performing the photolithography process. Accordingly, the same effect as in the first illustrative aspect can be acquired, and, at the same time, the number of masking processes can be reduced by two processes compared with the first illustrative aspect and by one processes compared with second or third illustrative aspect. Thus, the effect in improvement of productivity is achieved.

Regarding the method of forming a photo resist, which includes an opening and a thick film part used in the second illustrative aspect, third illustrative aspect, fourth illustrative aspect and illustrative modification, having different thicknesses, there is another method other than the method of performing an exposure processing using the halftone mask having different light transmittances response to its regions. For example, although the another method needs exposure processes more than two times, the another method uses a plurality of general photo masks, which have light shielding regions and opening regions and differ in a position of the opening regions with each of the photo masks. Thereafter, exposure processing with exposure light a having different amount is performed by using each of the photo masks. Thus, an exposure processing with the exposure light having 3 or more kinds of different intensities in performed response to each of the regions. As a result, one photo resist having different thicknesses response to each of the regions may be formed. In this case, it is possible to form the photo resist having different thicknesses only by using the general photo mask without using a halftone mask having a halftone exposure region. Also, in the second, third and fourth illustrative aspects and the illustrative modification, although the case where a positive type photo resist is used was described as an example, a negative type photo resist may be used. In this case, it goes without saying that the relationship of large or small in the amount of exposure light or the relationship of the opening region and the light shielding region should be changed reversely.

In the second, third and fourth illustrative aspects and the illustrative modification, the present invention is described as a liquid crystal display device as an example of a semiconductor device using a TFT structure similar to the first illustrative aspect. However, the present invention can be applied to a plane type display device (flat panel display) such as an organic EL display device, etc., as display devices other than a liquid crystal or a photoelectric conversion device, etc., such as an image sensor as a semiconductor device other than a display device. Even in this case, the same effect as the second, third and fourth illustrative aspects and the illustrative modification can be acquired, in addition to the effect in the configuration as described in the first illustrative aspect.

Although, the illustrative aspects and the modification thereof have been shown and described with reference to the drawings, the described illustrates only an example. The present invention does not have to be limited by each of the illustrative aspects in all respects. The scope of the present invention is defined by claims and various changes in the equivalent meanings.

What is claimed is:

1. A semiconductor device comprising:
a thin film transistor substrate including a thin film transistor; and
a driving circuit embedded in the thin film transistor substrate,
wherein the thin film transistor substrate comprises:
the thin film transistor comprises:
a gate electrode that is formed on an insulating substrate;
a gate insulating film that is formed on the insulating substrate and the gate electrode;
a semiconductor layer that is formed on the gate insulating film, wherein a crystalline semiconductor part formed at least part of the semiconductor layer includes a channel region;
a channel protecting film that is formed on the channel region of the semiconductor layer to protect the channel region; and
a source electrode and a drain electrode that are formed to connect with the semiconductor layer; and
a wiring converting unit that directly and electrically connects a first wiring layer and a second wiring layer through a first contact hole formed in the gate insulating film in the driving circuit,
wherein the first wiring layer is formed at the same layer as the gate electrode on the insulating substrate; and
wherein the second wiring layer is formed at the same layer as the source electrode and the drain electrode.

2. The semiconductor device according to claim 1, wherein the semiconductor
device is a liquid crystal display device, wherein the liquid crystal display device comprises;
a counter substrate that faces the thin film transistor substrate;
a seal that bonds the thin film transistor substrate and the counter substrate together; and
a liquid crystal that is sealed into a region surrounded by the thin film transistor substrate, the counter substrate and the seal,
wherein the wiring converting unit is arranged at the outside of the region surrounded by the seal.

3. The semiconductor device according to claim 1, wherein the semiconductor device is a liquid crystal display device,
wherein the liquid crystal display device comprises:
a counter substrate that faces the thin film transistor substrate;
a seal that bonds the thin film transistor substrate and the counter substrate together; and
a liquid crystal that is sealed into a region surrounded by the thin film transistor substrate, the counter substrate and the seal;
wherein a counter electrode is arranged on a surface of the liquid crystal side in the counter substrate, and
wherein the wiring converting unit is arranged near the seal.

4. The semiconductor device according to claim 1, wherein the semiconductor device is a liquid crystal display device,
wherein the liquid crystal display device comprises:
a protective insulating film that covers the second wiring layer in the wiring converting unit, the source electrode and the drain electrode;
a second contact hole that is formed in the protective insulating film; and
a pixel electrode that is connected to the drain electrode through the second contact hole formed in the protective insulating film.

5. The semiconductor device according to claim 1,
wherein the gate insulating film contacts with the crystalline semiconductor part of the semiconductor layer,
wherein the crystalline semiconductor part is made of a crystalline silicon film, and
wherein a part contacting with the crystalline semiconductor part in the gate insulating film is made of a silicon oxide film.

6. The semiconductor device according to claim 1,
wherein the channel protecting film contacts with the crystalline semiconductor part of the semiconductor layer,
wherein the crystalline semiconductor part is made of a crystalline silicon film, and
wherein a part contacting with the crystalline semiconductor part in the channel protecting film is made of a silicon oxide film.

7. The semiconductor device according to claim 6,
wherein the channel protecting film is formed by a stacked film including a lower layer made of a silicon oxide film and an upper layer made of a silicon nitride film.

8. The semiconductor device according to claim 1, wherein the entire semiconductor layer is formed by a crystalline semiconductor part

9. The semiconductor device according to claim 1,
wherein the crystalline semiconductor part of the semiconductor layer is made of a microcrystalline silicon layer.

10. The semiconductor device according to claim 1,
wherein a source region and a drain region doped with impurities are formed in contacting portions of the source electrode and the drain electrode respectively.

11. A method of manufacturing a semiconductor device, the semiconductor device comprises a thin film transistor substrate including a thin film transistor and a driving circuit embedded in the thin film transistor substrate, the manufacturing method comprising
forming a gate electrode on an insulating substrate;
forming a gate insulating film on the insulating substrate and the gate electrode;
forming a semiconductor layer on the gate insulating film, wherein a crystalline semiconductor part formed at least part of the semiconductor layer includes a channel region;
forming a channel protecting film on the channel region of the semiconductor layer to protect the channel region; and
forming a source electrode and a drain electrode to be connected with the semiconductor layer; and
forming a wiring converting unit that directly and electrically connects a first wiring layer and a second wiring layer through a first contact hole formed in the gate insulating film in the driving circuit,
wherein the first wiring layer is formed at the same layer as the gate electrode on the insulating substrate; and
wherein the second wiring layer is formed at the same layer as the source electrode and the drain electrode,

12. A method of manufacturing a semiconductor device according to claim 10,
wherein both forming of the first contact hole that directly and electrically connects the first wiring layer and the second wiring layer and forming of the channel protecting film or the semiconductor layer are performed by a single photolithography process.

13. The method of manufacturing a semiconductor device according to claim 12, further comprising:
forming a semiconductor film and an inorganic insulating film on the gate insulating film in sequence;
forming a photo resist on the inorganic insulating film, wherein the photo resist has a thick film part, which is located at a region where the channel protecting film or the semiconductor layer is to be formed, and an opening, which is located at a region where the first contact hole that directly and electrically connects the first wiring layer contact and the second wiring layer is to be formed;
removing the inorganic insulating film, the semiconductor film, and the gate insulating film at the opening;
removing the photo resist by a thickness reducing process of the photo resist while leaving the thick film part;
removing the inorganic insulating film or semiconductor film outside the region covered with the photo resist of the thick film part; and
forming the channel protecting film or the semiconductor layer.

14. The method of manufacturing a semiconductor device according to claim 11,
wherein forming of the contact hole that directly and electrically connects the first wiring layer and the second wiring layer, forming of the channel protecting film, and forming of the semiconductor layer are performed by single photolithography process.

15. The method of manufacturing a semiconductor device according to claim 14, further comprising:
forming a semiconductor film and an inorganic insulating film on the gate insulating film in sequence;
forming a photo resist on the inorganic insulating film, wherein the photo resist has a first thick film part, which is located at a region where the semiconductor layer to be formed, a second thick film part, which is thicker than the first thick film part and is located at a region where the channel protecting film is to be formed, and an opening at a region to be formed the first contact hole that directly and electrically connects the first wiring layer contact and the second wiring layer;
removing the inorganic insulating film, the semiconductor film, and the gate insulating film at the opening;
removing the photo resist by a first thickness reducing process of the photo resist, while leaving the first thick film part and the second thick film part;
removing the inorganic insulating film and the semiconductor film outside a region covered with the photo resist of the first thick film part and the second thick film part;
forming the semiconductor layer;
removing the photo resist of the first thick film part by a second thickness reducing process while leaving the second thick film part;
removing the inorganic insulating film outside a region covered with the photo resist of the second thick film part; and
forming the channel protecting layer.

16. The method of manufacturing a semiconductor device according to claim 14, further comprising:
forming a semiconductor film and an inorganic insulating film in sequence on a gate insulating film;
forming a photo resist on the inorganic insulating film, wherein the photo resist has a thick film part located at a region where the semiconductor layer is to be formed, and an opening located at a region where the first contact hole that directly and electrically connects the first wiring layer and the second wiring layer is to be formed;
removing the inorganic insulating film, semiconductor film, and gate insulating film at the opening;
removing the photo resist by a thickness reducing process while leaving the thick film part;
removing the inorganic insulating film and the semiconductor film outside a region covered with the photo resist of the thick film part to form the semiconductor layer;
removing the photo resist by an end-face set back process while leaving the region to be formed the channel protecting film;
removing the inorganic insulating film outside a region covered with the remaining photo resist after the end-face set-back process; and
forming the channel protecting layer.
